(19) United States
(12) Patent Application Publication
(10) Pub. No.: US 2025/0061560 A1
(43) Pub. Date: Feb. 20, 2025

(54) IMAGE PROCESSING FOR ON-CELL OVERLAY MEASUREMENT

(71) Applicant: SAMSUNG ELECTRONICS CO., LTD., Suwon-si (KR)

(72) Inventors: Minsu Kang, Suwon-si (KR); Kwang-Eun Kim, Suwon-si (KR); HuiSoo Kim, Suwon-si (KR); Seum Seo, Suwon-si (KR); Jeongho Ahn, Suwon-si (KR); Sungeun Lee, Suwon-si (KR); Chaeyoung Lee, Suwon-si (KR); Choonshik Leem, Suwon-si (KR); Woojin Jung, Suwon-si (KR)

(21) Appl. No.: 18/798,487

(22) Filed: Aug. 8, 2024

(30) Foreign Application Priority Data
Aug. 17, 2023 (KR) 10-2023-0107813

(51) Int. Cl. G06T 7/00; G06T 5/30; G06T 5/70; G06V 10/60; G06V 10/762; G06V 20/70

(52) U.S. Cl. CPC G06T 7/0008; G06T 5/30; G06T 5/70; G06V 10/60; G06V 10/762; G06V 20/70; G06T 2207/10061; G06T 2207/30148

(57) ABSTRACT

A parameter optimization method includes receiving a plurality of SEM images respectively corresponding to a plurality of positions on a semiconductor wafer in which a first pattern and a second pattern are disposed based on overlay settings, determining a primary optimization parameter set based on the plurality of SEM images, clustering the plurality of SEM images to a plurality of clusters based on image attributes, and determining a secondary optimization parameter set corresponding to each of the plurality of clusters based on SEM images included in each of the plurality of clusters from among the plurality of SEM images and the primary optimization parameters.

### CROSS-REFERENCE TO RELATED APPLICATIONS

This application claims priority under 35 U.S.C. § 119 to Korean Patent Application No. 10-2023-0107813 filed on Aug. 17, 2023, in the Korean Intellectual Property Office, the disclosure of which is incorporated by reference herein in its entirety.

### BACKGROUND

An overlay may be measured to determine the degree of distortion between patterns on a semiconductor wafer. The overlay measurement may be performed by identifying patterns on an image obtained by photographing the semiconductor wafer and calculating a relative position of the identified patterns. The image obtained by photographing the semiconductor wafer may be processed to accurately identify the patterns on the semiconductor wafer. Various parameters may be used in image processing. When each parameter is set to an optimal value, it is possible to accurately measure the overlay.

### SUMMARY

Some aspects of the present disclosure provide a parameter optimization method, an on-cell overlay measurement system, and an on-cell overlay measurement method capable of reducing a computational burden of determining an optimal parameter value.

Some aspects of the present disclosure provide a parameter optimization method, an on-cell overlay measurement system, and an on-cell overlay measurement method, which consider image attributes.

According to some implementations, a parameter optimization method includes receiving a plurality of SEM images respectively corresponding to a plurality of positions on a semiconductor wafer in which a first pattern and a second pattern are disposed based on overlay settings, determining a primary optimization parameter set based on the plurality of SEM images, clustering the plurality of SEM images to a plurality of clusters based on image attributes, and determining a secondary optimization parameter set corresponding to each of the plurality of clusters based on SEM images included in each of the plurality of clusters from among the plurality of SEM images and the primary optimization parameter set.

According to some implementations, an on-cell overlay measurement system includes a scanning electron microscope that obtains an SEM image from a semiconductor wafer in which a first pattern and a second pattern are disposed based on overlay settings, a parameter optimizer that receives the SEM image from the scanning electron microscope and transmits a parameter set and the SEM image, and an overlay measurement device that generates overlay information corresponding to the SEM image based on the parameter set and the SEM image. The parameter optimizer receives a plurality of SEM images, determines a primary optimization parameter set based on overlay settings and overlay information of the plurality of SEM images, clusters the plurality of SEM images to a plurality of clusters based on image attributes, and determines a secondary optimization parameter set corresponding to each of the plurality of clusters based on the primary optimization parameter set and overlay information and overlay settings of SEM images included in each of the plurality of clusters.

According to some implementations, an on-cell overlay measurement method includes forming a first pattern and a second pattern in a semiconductor wafer based on overlay settings, photographing a plurality of SEM images associated with a plurality of positions of the semiconductor wafer, determining a primary optimization parameter set based on the plurality of SEM images, clustering the plurality of SEM images to a plurality of clusters based on image attributes, determining a secondary optimization parameter set corresponding to each of the plurality of clusters based on SEM images included in each of the plurality of clusters and the primary optimization parameter set, and measuring an overlay of each of the plurality of SEM images based on the secondary optimization parameter set corresponding to each of the plurality of clusters.

### BRIEF DESCRIPTION OF THE FIGURES

The above and other objects and features of the present disclosure will become apparent by describing in detail implementations thereof with reference to the accompanying drawings.

FIG. 1 is a block diagram illustrating an on-cell overlay measurement system according to some implementations of the present disclosure.

FIG. 2 is a diagram illustrating an example of a parameter set of FIG. 1.

FIG. 3 is a diagram illustrating processed SEM images and identified patterns, according to some implementations of the present disclosure.

FIG. 4 is a flowchart illustrating a parameter optimization method according to some implementations of the present disclosure.

FIG. 5 is a flowchart illustrating determination of a primary optimization parameter set.

FIG. 6 is a diagram for illustrating parameter sets according to some implementations of the present disclosure.

FIGS. 7A and 7B are diagrams illustrating an operation of adjusting a target parameter set, according to some implementations of the present disclosure.

FIG. 8 is a diagram illustrating an example of an operation of adjusting a target parameter set, according to some implementations of the present disclosure.

FIG. 9 is a flowchart illustrating calculation of an image processing score, according to some implementations of the present disclosure.

FIG. 10 is a flowchart illustrating generation of overlay information, according to some implementations of the present disclosure.

FIG. 11 is a diagram illustrating patterns disposed on a semiconductor wafer, according to some implementations of the present disclosure.

FIG. 12 is a diagram illustrating pattern identification and pattern quantification, according to some implementations of the present disclosure.

FIG. 13 is a diagram illustrating a first pattern and a second pattern identified in a pattern unit, according to some implementations of the present disclosure.

FIG. 14 is a diagram illustrating a linear regression which is based on overlay settings and overlay information.

FIGS. 15A and 15B are diagrams attributes of a plurality of SEM images depending on image attributes, according to some implementations of the present disclosure.

FIGS. 16A to 16C are diagrams illustrating a secondary optimization parameter set for each of a plurality of clusters.

FIG. 17 is a diagram illustrating an example of an on-cell overlay measurement system according to some implementations of the present disclosure.

FIG. 18 is a flowchart illustrating an on-cell overlay measurement method according to some implementations of the present disclosure.

### DETAILED DESCRIPTION

Below, implementations of the present disclosure will be described in detail and clearly to such an extent that an ordinary one in the art easily carries out the present disclosure. Certain details, such as details of components and structures, are provided only for the overall understanding of implementations of the present disclosure. Therefore, modifications of the implementations disclosed herein may be made by one skilled in the art without departing from the spirit and scope of the disclosure. Moreover, descriptions of well-known functions and structures are omitted for clarity and conciseness. Terms used in the specification are terms defined in consideration of functions of the present disclosure and are not limited thereto. The definitions of the terms should be determined based on the contents throughout the specification.

In the detailed description, components that are described with reference to the terms “driver”, “block”, “unit”, etc. will be implemented with software, hardware, or a combination thereof. For example, the software may be a machine code, firmware, an embedded code, or application software. For example, the hardware may include an electrical circuit, an electronic circuit, a processor, a computer, integrated circuit cores, a pressure sensor, an inertial sensor, a micro electro mechanical system (MEMS), a passive element, or a combination thereof.

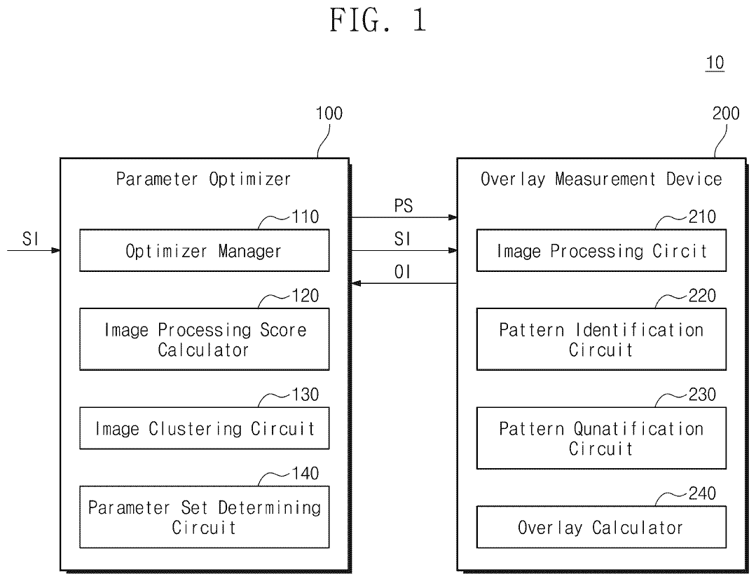

FIG. 1 is a block diagram illustrating an on-cell overlay measurement system according to some implementations of the present disclosure. Referring to FIG. 1, an on-cell overlay measurement system 10 may include a parameter optimizer 100 and an overlay measurement device 200.

The parameter optimizer 100 may receive a scanning electron microscope (SEM) image SI from the outside. For example, the parameter optimizer 100 may receive the SEM image SI photographed through a scanning electron microscope, where “photographed” as used herein includes images captured by electron microscopy. The parameter optimizer 100 may optimize a plurality of parameters that are used when the overlay measurement device 200 processes the SEM image SI and identifies patterns on the SEM image SI. To optimize the plurality of parameters that are used in the processing of the SEM image SI and the identification of patterns on the SEM image SI, the parameter optimizer 100 may transmit a parameter set PS including a plurality of parameters to the overlay measurement device 200. The parameter optimizer 100 may receive overlay information OI, which is generated based on the parameter set PS and the SEM image SI, from the overlay measurement device 200. The parameter optimizer 100 may adjust the plurality of parameters, which are used in the overlay measurement device 200, based on the received overlay information OI.

The SEM image SI that is an image obtained by photographing a part of a semiconductor wafer, in which a plurality of patterns are disposed, through the scanning electron microscope, may correspond to raw image data that has not undergone additional processing. The parameter optimizer 100 may obtain a plurality of SEM images SI respectively corresponding to a plurality of positions on a single semiconductor wafer. The positions at which the SEM images SI are photographed may be determined on the semiconductor wafer in a lattice manner, a random manner, or a pseudo random manner.

The parameter set PS may be a combination of a plurality of parameters used in the processing of the SEM image SI and the identification of patterns on the SEM image SI. Some or all of the plurality of parameters included in the parameter set PS may be used to process the SEM image SI such that the overlay measurement device 200 is capable of measuring the overlay of the plurality of patterns disposed on the semiconductor wafer and/or may be used to determine the plurality of patterns on the processed SEM image SI. For example, the parameter set PS may include at least one of a parameter associated with noise processing of an SEM image (e.g., blur processing), a parameter associated with a binarization filter by thresholding, a parameter associated with morphological transformation, and a parameter associated with a characteristic of identification-targeted patterns. A configuration of the parameter set PS may be changed depending on settings.

The overlay measurement device 200 may process the SEM image SI based on the received parameter set PS and may identify patterns on the processed SEM image SI. The overlay measurement device 200 may quantify the identified patterns and may calculate an on-cell overlay corresponding to the SEM image SI based on the quantified patterns. The overlay measurement device 200 may output the overlay information OI generated through the calculation of the on-cell overlay. The overlay information OI may include an overlay value of a first axis (e.g., an X-axis) and an overlay value of a second axis (e.g., a Y-axis) perpendicular to the first axis.

The parameter optimizer 100 may include an optimizer manager 110, an image processing score calculator 120, an image clustering circuit 130, and a parameter set determining circuit 140.

The optimizer manager 110 may manage an overall operation of the parameter optimizer 100. The optimizer manager 110 may control the image processing score calculator 120 to obtain an image processing score of the parameter set PS. The optimizer manager 110 may control the image clustering circuit 130 such that the plurality of SEM images SI are clustered in a plurality of clusters. The optimizer manager 110 may control the parameter set determining circuit 140 such that a parameter set optimized for the SEM images SI is determined.

The image processing score calculator 120 may calculate the image processing score of the parameter set PS based on the overlay information OI received from the overlay measurement device 200. To calculate the image processing score, the parameter optimizer 100 may transmit the plurality of SEM images SI for each parameter set PS. The parameter optimizer 100 may receive the overlay information OI corresponding to each of the plurality of SEM images SI. The image processing score calculator 120 may calculate the image processing score based on the degree of matching between overlay settings applied when patterns are formed on a semiconductor wafer and the overlay information OI corresponding to each of the received SEM images SI. To calculate the image processing score, the image processing score calculator 120 may generate a linear model through a linear regression analysis between the overlay settings and the overlay information OI received from the overlay measurement device 200. The linear model may be expressed in a linear equation. The image processing score calculator 120 may calculate the image processing score based on the linear model.

The image processing score calculator 120 may calculate an image processing score associated with some or all of the obtained SEM images SI. For example, to determine a primary optimization parameter set corresponding to all the obtained SEM images SI, the image processing score calculator 120 may calculate an image processing score based on the overlay settings and the overlay information OI of each of all the obtained SEM images SI. To determine a secondary optimization parameter set corresponding to a first cluster, the image processing score calculator 120 may calculate an image processing score based on the overlay settings and the overlay information OI of each of SEM images SI included in the first cluster. Also, to determine a secondary optimization parameter set corresponding to a second cluster, the image processing score calculator 120 may calculate an image processing score based on the overlay settings and the overlay information OI of each of SEM images SI included in the second cluster.

The image clustering circuit 130 may cluster the plurality of SEM images SI received from the outside in a plurality of clusters based on image attributes. For example, when the image clustering circuit 130 clusters the plurality of SEM images SI, an average of brightness of the SEM images SI and the standard deviation of brightness of the SEM images SI may be used as the image attributes. The plurality of SEM images SI may be labeled depending on relevant clusters. For example, the image clustering circuit 130 may label SEM images SI included in the first cluster among the plurality of clusters as a first label and may label SEM images SI included in the second cluster among the plurality of clusters as a second label.

The parameter set determining circuit 140 may determine an optimized parameter set based on the image processing score of each of the parameter sets PS. The parameter set determining circuit 140 may determine the primary optimization parameter set corresponding to all the obtained SEM images SI.

The parameter set determining circuit 140 may determine the secondary optimization parameter sets respectively corresponding to the plurality of clusters based on the primary optimization parameter set. For example, the parameter set determining circuit 140 may determine the secondary optimization parameter set corresponding to the first cluster based on the image processing score calculated by using the SEM images SI labeled as the first label from among all the obtained SEM images SI and may determine the secondary optimization parameter set corresponding to the second cluster based on the image processing score calculated by using the SEM images SI labeled as the second label from among all the obtained SEM images SI.

When the parameter set determining circuit 140 determines the primary optimization parameter set or the secondary optimization parameter sets, the parameter set determining circuit 140 may use a gradient decent method or a method similar to the gradient decent method. For example, the parameter set determining circuit 140 may compare an image processing score of a target parameter set and an image processing score of a maximum neighboring parameter set among neighboring parameter sets. When the image processing score of the maximum neighboring parameter set is enhanced compared to the image processing score of the target parameter set, the parameter set determining circuit 140 may adjust parameters included in the target parameter set by using parameter values of the maximum neighboring parameter set. When the image processing score of the maximum neighboring parameter set is not enhanced compared to the image processing score of the target parameter set, the parameter set determining circuit 140 may determine that the target parameter set is the primary optimization parameter set. The parameter set determining circuit 140 may use the primary optimization parameter set and the clustered SEM images to determine the secondary optimization parameter set. For example, the parameter set determining circuit 140 may compare the image processing score of the primary optimization parameter set and the image processing score of the maximum neighboring parameter set. The parameter set determining circuit 140 may determine the optimized parameter set when the image processing score of the maximum neighboring parameter set is enhanced compared to the image processing score of the target parameter set, that is, by repeating the comparison of image processing scores and the adjustment of parameter values.

The parameter optimizer 100 may include a computing device such as a desktop personal computer (PC), a laptop personal computer, or a tablet personal computer (PC).

The overlay measurement device 200 may include an image processing circuit 210, a pattern identification circuit 220, a pattern quantification circuit 230, and an overlay calculator 240.

The image processing circuit 210 may process the received SEM image SI based on some or all of parameter values included in the parameter set PS received from the parameter optimizer 100. The image processing circuit 210 may perform at least one processing operation with respect to the SEM image SI. For example, the image processing circuit 210 may generate the processed SEM image SI by performing at least one of the following image processing operations with respect to the SEM image SI: blur processing, thresholding processing, morphological transformation processing, erode processing, and dilation processing.

The pattern identification circuit 220 may identify patterns on the processed SEM image SI based on some or all of the parameter values included in the received parameter set PS. For example, the pattern identification circuit 220 may identify a first pattern and a second pattern on the processed SEM image SI.

The pattern identification circuit 220 may calculate a pattern identification rate. The pattern identification rate may be calculated as a ratio of the number of pattern units actually identified from an SEM image to the maximum number of pattern units capable of being identified from a single SEM image. The overlay measurement device 200 may output the pattern identification rate for each SEM image SI to the parameter optimizer 100, such that the parameter optimizer 100 calculates an image parameter score further based on the pattern identification rate. The pattern unit refers to the most basic unit necessary to calculate the on-cell overlay between the first pattern and the second pattern.

The pattern quantification circuit 230 may quantify the patterns identified to calculate the on-cell overlay. For example, the pattern quantification circuit 230 may determine a reference point of each of the first pattern and the second pattern identified to calculate the on-cell overlay.

The pattern quantification circuit 230 may calculate a quantification success rate. The quantification success rate may be calculated as a ratio of the number of pattern units actually quantified from an SEM image to the maximum number of pattern units capable of being quantified from a single SEM image. The overlay measurement device 200 may output the quantification success rate for each SEM image SI to the parameter optimizer 100, such that the parameter optimizer 100 calculates an image parameter score further based on the quantification success rate. When the parameter optimizer 100 calculates the image processing score, the parameter optimizer 100 may use one of the pattern identification rate or the quantification success rate.

The overlay calculator 240 may calculate the overlay corresponding to the SEM image SI based on the quantified patterns. The overlay calculator 240 may calculate the on-cell overlay between the first pattern and the second pattern depending on a relative position of the reference point determined by the pattern quantification circuit 230 and a second reference point.

The overlay measurement device 200 may include a computer system such as a workstation or a data collection server.

In addition, the overlay measurement device 200 may receive the SEM image SI from the scanning electron microscope. The overlay measurement device 200 may store the received SEM image SI in a storage device. The overlay measurement device 200 may process the SEM image SI stored in the storage device by using the parameter set PS received from the parameter optimizer 100. That is, the overlay measurement device 200 may receive only the parameter set PS and may perform processing and pattern identification with respect to the SEM image SI stored in the storage device.

The parameter optimizer 100 may determine the primary optimization parameter set by using all the obtained SEM images SI. The parameter optimizer 100 may cluster all the obtained SEM images SI in the plurality of clusters based on image attributes. The parameter optimizer 100 may determine the secondary optimization parameter set corresponding to each of the plurality of clusters.

According to the above description, the parameter optimizer 100 may determine the optimized parameter set without performing performance evaluation with respect to all parameter sets capable of being combined. That is, a time and the amount of computation necessary to determine parameters used in image processing and pattern identification may decrease.

The parameter optimizer 100 may finely tune the optimized parameter set based on the image attributes of the SEM images SI. This may mean that the accuracy of the on-cell overlay measured from the semiconductor wafer increases.

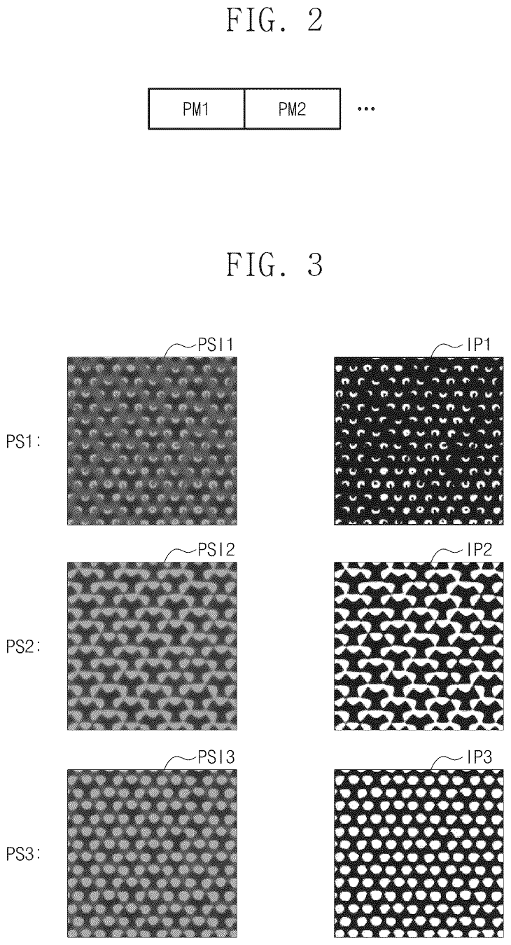

FIG. 2 is a diagram illustrating an example of a parameter set of FIG. 1. Referring to FIG. 2, the parameter set PS may include a first parameter PM1 and a second parameter PM2.

The parameters PM1, PM2, etc. included in the parameter set PS may be used in image processing or pattern identification that is performed in the overlay measurement device 200. For example, the first parameter PM1 or the second parameter PM2 may be a parameter associated with various kinds of image processing, such as blur processing, thresholding processing, morphological transformation processing, erode processing, and/or dilation processing, when image processing is performed in the overlay measurement device 200. In detail, the first parameter PM1 may be a parameter associated with a Gaussian filter that is used in blur processing. For example, the first parameter PM1 may be at least one of a kernel size of the Gaussian filter or the standard deviation of the Gaussian filter. The second parameter PM2 may be a parameter associated with adaptive thresholding processing of the thresholding processing. For example, the second parameter PM2 may be at least one of a block size, a block average correction value, or a thresholding processing threshold value, which is to be applied in the adaptive thresholding processing.

When pattern identification is performed in the overlay measurement device 200, the parameters PM1, PM2, etc. included in the parameter set PS may be parameters associated with pattern identification, such as a pattern size and a maximum value/a minimum value of a ratio of the major axis to the minor axis of the fitting ellipse of a pattern.

The parameters PM1, PM2, etc. included in the parameter set PS may be selected within a range, in which some or all of parameters used in image processing and pattern identification are included, depending on settings. For example, according to a first setting, the parameter set PS may only include a parameter associated with blur processing and a parameter associated with adaptive thresholding processing. According to a second setting, the parameter set PS may further include at least one parameter associated with pattern identification, in addition to the parameter associated with blur processing and the parameter associated with adaptive thresholding processing. According to a third setting, the parameter set PS may include only parameters associated with pattern identification. According to a fourth setting, the parameter set PS may include all the parameters used in image processing and pattern identification.

Parameters that are included in the parameter set PS may be determined depending on an optimization target. With regard to parameters not included in the parameter set PS, a preset value may be used in image processing or pattern identification of the overlay measurement device 200.

Each of the parameters PM1, PM2, etc. included in the parameter set PS may be a parameter that is capable of being adjusted depending on an adjustment unit. In some implementations, when the adjustment unit of the first parameter PM1 is “1”, the first parameter PM1 may be adjusted as follows: 10, 11, and 12. In some implementations, when the adjustment unit of the second parameter PM2 is “2”, the second parameter PM2 may be adjusted as follows: 10, 12, and 14.

FIG. 3 is a diagram illustrating processed SEM images and identified patterns, according to some implementations of the present disclosure. Referring to FIG. 3, different patterns IP1, IP2, and IP3 may be identified on an SEM image depending on parameter sets PS1, PS2, and PS3.

The overlay measurement device 200 of FIG. 1 may receive the parameter sets PS1, PS2, and PS3 and the SEM image SI. Depending on each of the parameter sets PS1, PS2, and PS3, the overlay measurement device 200 may generate processed SEM images PSI1, PIS2, and PSI3 by processing the SEM image SI and may identify a preset target pattern among a plurality of patterns on the SEM image SI from each of the processed SEM images PSI1, PIS2, and PSI3. In FIG. 3, “IP1” indicates a target pattern that the overlay measurement device 200 identifies depending on the parameter set PS1, “IP2” indicates a target pattern that the overlay measurement device 200 identifies depending on the parameter set PS2, and “IP3” indicates a target pattern that the overlay measurement device 200 identifies depending on the parameter set PS3.

Even though the overlay measurement device 200 performs image processing and pattern identification with respect to the same SEM image SI, different target patterns may be respectively identified depending on the received parameter sets PS1, PS2, and PS3. In the case of the parameter set PS1 and the parameter set PS2, a target pattern actually disposed on the semiconductor wafer may be different from the identified target pattern. When the patterns identified by the overlay measurement device 200 have a large difference from the patterns disposed on the semiconductor wafer, there is a limitation in measuring the on-cell overlay accurately. Accordingly, there is a need to optimize the parameter set PS for the purpose of accurately measuring the on-cell overlay. When the overlay measurement device 200 performs image processing and pattern identification with respect to the SEM image SI by using the optimized parameter set PS, a result of measuring the on-cell overlay may have higher reliability.

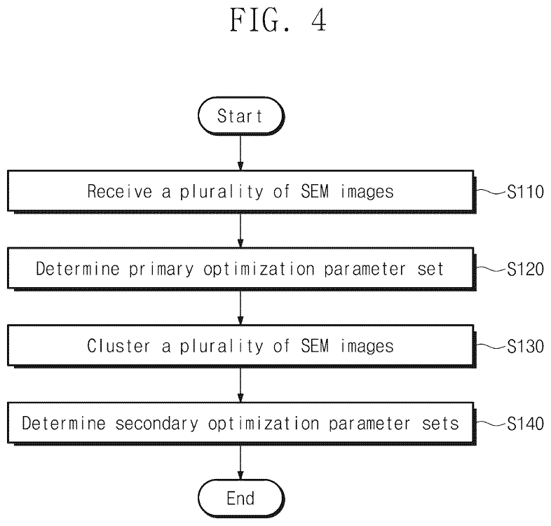

FIG. 4 is a flowchart illustrating a parameter optimization method according to some implementations of the present disclosure. Referring to FIG. 4, the parameter optimization method may include receiving a plurality of SEM images respectively corresponding to a plurality of positions on a wafer where a first pattern and a second pattern are disposed based on overlay settings (S110). Operation S110, that is, the receiving of the plurality of SEM images may be performed by the parameter optimizer 100. The plurality of SEM images are images photographed at a plurality of positions on a semiconductor wafer through a scanning electron microscope. Each of the plurality of positions on the semiconductor wafer may be determined in a lattice manner, a random manner, or a pseudo random manner. The plurality of SEM images may be images photographed through a high-voltage scanning electron microscope (HVSEM).

The parameter optimization method according to some implementations of the present disclosure may include determining a primary optimization parameter set based on the plurality of SEM images (S120). In operation S120, that is, in the determining of the primary optimization parameter set, the parameter optimizer 100 may transmit all the obtained SEM images SI for each of the parameter sets PS. The overlay measurement device 200 may receive overlay information corresponding to each of the plurality of SEM images SI. The parameter optimizer 100 may calculate an image processing score of each of the parameter sets PS based on the overlay information and the overlay settings corresponding to each of the plurality of SEM images SI. The parameter optimizer 100 may determine the primary optimization parameter set based on the image processing score of each of the parameter sets PS.

The parameter optimization method according to some implementations of the present disclosure may include clustering the plurality of SEM images in a plurality of clusters (S130). The parameter optimizer 100 may use the average of brightness of the SEM image SI and the standard deviation of brightness of the SEM image SI among the image attributes. When the parameter optimizer 100 clusters the plurality of SEM images to the plurality of clusters, a K-means method may be used. In the case of using the K-means method, the number of clusters may be determined through an elbow method, a silhouette method, etc. When the parameter optimizer 100 clusters the plurality of SEM images to the plurality of clusters, the parameter optimizer 100 may further use a K-nearest neighbor (K-NN) method. The parameter optimizer 100 may cluster the plurality of SEM images to the plurality of clusters based on the image attributes, through various methods capable of being selected by one skilled in the art, in addition or instead of to the K-means method.

The parameter optimization method according to some implementations of the present disclosure may include determine a secondary optimization parameter set corresponding to each of the plurality of clusters based on a plurality of SEM images included in each of the plurality of clusters and based on the primary optimization parameter set. The parameter optimizer 100 may transmit a plurality of SEM images included in a first cluster to the overlay measurement device 200, for each of the plurality parameter sets PS including the primary optimization parameter set. The overlay measurement device 200 may generate the overlay information for each of the plurality of SEM images SI included in the first cluster. The parameter optimizer 100 may calculate the image processing scores of the parameter sets PS based on overlay information and overlay settings corresponding to each of the plurality of SEM images SI included in the first cluster. The parameter optimizer 100 may determine the secondary optimization parameter set of the first cluster based on the image processing scores. The parameter optimizer 100 may determine the secondary optimization parameter set of a second cluster by using a plurality of SEM images SI included in the second cluster.

In implementations in which the overlay measurement device 200 stores the SEM images SI in the storage device, the operation in which the parameter optimizer 100 transmits a plurality of SEM images may be omitted.

According to the above description, the parameter optimization method according to some implementations of the present disclosure may determine the optimized parameter set without performing performance evaluation with respect to all parameter sets capable of being combined. That is, a time and the amount of computation necessary to determine parameters used in image processing and pattern identification may decrease.

The parameter optimization method according to some implementations of the present disclosure may make it possible to finely tune the optimized parameter set of each cluster based on the image attributes of the SEM images SI. This may mean that the accuracy of the on-cell overlay measured from the semiconductor wafer increases.

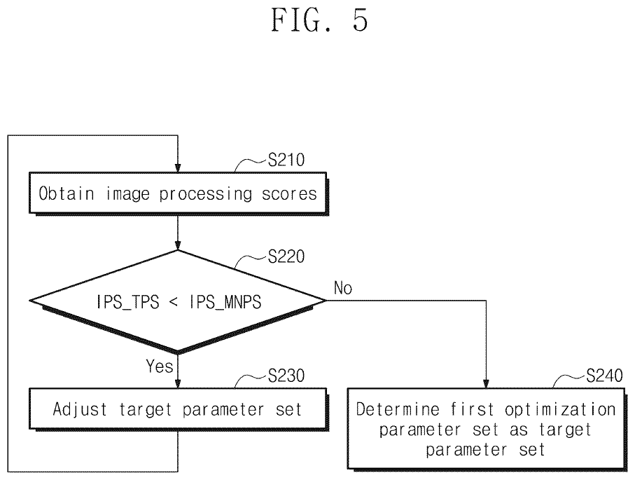

FIG. 5 is a flowchart illustrating how to determine a primary optimization parameter set, e.g., in operation S120 of FIG. 4. Referring to FIG. 5, operation S120, that is, the determining of the primary optimization parameter set may include obtaining an image processing score of each of a target parameter set and neighboring parameter sets (S210). To calculate the image processing score of each of the target parameter set and the neighboring parameter sets, the parameter optimizer 100 may transmit the target parameter set and the neighboring parameter sets to the overlay measurement device 200. When the parameter optimizer 100 transmits the target parameter set and the neighboring parameter sets, the parameter optimizer 100 may transmit a plurality of SEM images SI for each parameter set. The overlay measurement device 200 may output the overlay information OI, which corresponds to the parameter set and the plurality of SEM images SI. The parameter optimizer 100 may calculate an image processing score for each of the target parameter set and the neighboring parameter sets, based on the overlay settings applied when patterns are formed on a semiconductor wafer and the received overlay information OI. That is, with regard to the target parameter set, the overlay information OI may be output for each of the plurality of SEM images SI, and the parameter optimizer 100 may calculate the image processing score based on the overlay settings and the overlay information OI of each of the plurality of SEM images SI. As in the above method, the parameter optimizer 100 may calculate an image processing score for each of the neighboring parameter sets, as well as the target parameter set.

The target parameter set is a parameter set that is used as a reference for comparing image processing scores for the purpose of determining the primary optimization parameter set. An initial target parameter set may be a preset parameter set. That is, a plurality of parameter values included in the initial target parameter set may be set in advance.

The neighboring parameter sets mean parameter sets in which at least one of a plurality of parameters of the target parameter set is adjusted as much as a given distance. For example, a parameter set including parameter 1 and parameter 2 may be expressed by [parameter 1, parameter 2]. Assuming that the target parameter set is [10, 10], the given distance is “1”, and the adjustment unit of parameter 1 and parameter 2 is “1”, the neighboring parameter sets may include [9, 9], [9, 10], [9, 11], [10, 9], [10, 11], [11, 9], [11, 10], and [11, 11].

As another example, assuming that the target parameter set is [10, 20], the given distance is “2”, the adjustment unit of parameter 1 is “2”, and the adjustment unit of parameter 2 is “1”, the neighboring parameter sets may include [6, 18], [6, 19], [6, 20], [6, 21], [6, 22], [8, 18], [8, 19], [8, 20], [8, 21], [8, 22], [10, 18], [10, 19], [10, 21], [10, 22], [12, 18], [12, 19], [12, 20], [12, 21], [12, 22], [14, 18], [14, 19], [14, 20], [14, 21], and [14, 22].

The number of neighboring parameter sets may depend on a given distance and the number of parameters constituting a parameter set. As the number of parameters constituting a parameter set increases and as the given distance increases, the number of neighboring parameter sets may increase.

Operation S120, that is, the determining of the primary optimization parameter set may include comparing an image processing score IPS_TPS of the target parameter set and an image processing score IPS_MNPS of a maximum neighboring parameter set (S220). The maximum neighboring parameter set is a parameter set having the greatest image processing score from among the neighboring parameter sets.

Operation S120, that is, the determining of the primary optimization parameter set may include adjusting the target parameter set to the maximum neighboring parameter set based on the image processing score IPS_TPS of the target parameter set being smaller than the maximum image processing score IPS_MNPS of the neighboring parameter sets (Yes in operation S220). After the target parameter set is adjusted, there may be performed operation S210, that is, obtaining an image processing score of each of the adjusted target parameter set and neighboring parameter sets of the adjusted target parameter set. In this case, the parameter optimizer 100 may omit the calculation of the image processing score with regard to parameter sets whose image processing scores are already calculated. That is, the parameter optimizer 100 may calculate an image processing score only with respect to parameter sets, whose image processing scores are not calculated, from among the neighboring parameter sets of the adjusted target parameter set.

Operation S120, that is, the determining of the primary optimization parameter set may include determining that the target parameter set is the primary optimization parameter set, based on the image processing score IPS_TPS of the target parameter set being greater than or equal than the maximum image processing score IPS_MNPS of the neighboring parameter sets (No in operation S220). The case where an image processing score of a target parameter set is greater than or equal to an image processing score of each of neighboring parameter sets corresponds to the case where performance of image processing or pattern identification in the overlay measurement device 200 is not improved even though parameters are adjusted. The parameter optimizer 100 may determine that a current target parameter set is the primary optimization parameter set for the plurality of SEM images SI.

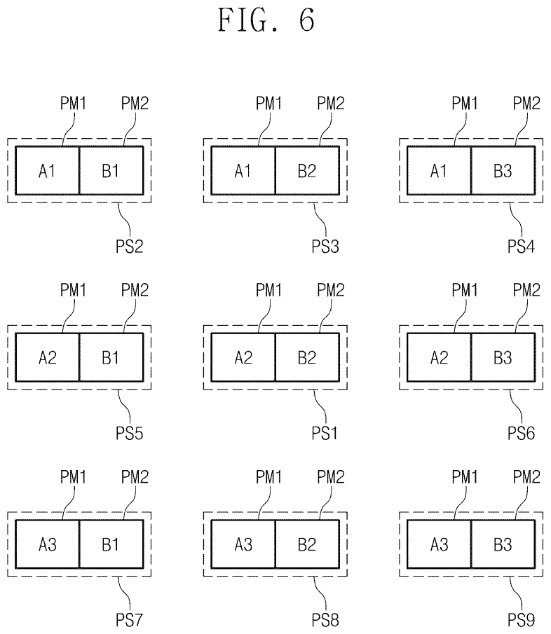

FIG. 6 is a diagram for describing parameter sets according to some implementations of the present disclosure. Referring to FIG. 6, each of parameter sets PS1, PS2, . . . , PS9 may include a plurality of parameters PM1 and PM2.

A value of the first parameter PM1 included in the parameter set PS1 is “A2”, and a value of the second parameter PM2 included therein is “B2”. The parameter set PS1 corresponds to a combination of the parameter values A2 and B2.

Each of the parameter sets PS2 to PS9 includes parameter values obtained by adjusting at least one of the parameter values A2 and B2 of the parameter set PS1 as much as the adjustment unit. For example, the parameter set PS2 may include a parameter value A1 obtained by adjusting the parameter value A2 as much as the adjustment unit and a parameter value B1 obtained by adjusting the parameter value B2 as much as the adjustment unit. The parameter set PS3 may include parameter values A1 and B2. The parameter set PS4 may include parameter values A1 and B3. Each of parameter sets PS5 and PS6 may include A3, B1, or B3.

The parameter sets PS2 to PS9 may correspond to neighboring parameter sets that are spaced from the parameter set PS1 as much as the set distance of “1”. To calculate an image processing score according to a combination of the plurality of parameters PM1 and PM2, the parameter optimizer 100 may transmit, to the overlay measurement device 200, the parameter set PS1 corresponding to the target parameter set and the parameter sets PS2 to PS9 corresponding to the neighboring parameter sets. When transmitting each of the parameter set PS1 and the parameter sets PS2 to PS9 to the overlay measurement device 200, the parameter optimizer 100 may transmit all the obtained SEM images SI to the overlay measurement device 200. In other words, when the parameter set PS1 is transmitted, all the obtained SEM images SI may be transmitted. Also, when the parameter set PS2 is transmitted, all the SEM images SI may be transmitted.

When transmitting each of the parameter set PS1 and the parameter sets PS2 to PS9 to the overlay measurement device 200, the parameter optimizer 100 may transmit some (e.g., less than all, or a subset of) the obtained SEM images SI to the overlay measurement device 200. For example, when the parameter set PS1 is transmitted, SEM images SI included in a first cluster may be transmitted. Also, when the parameter set PS2 is transmitted, the parameter optimizer 100 may only transmit SEM images SI included in a second cluster.

The number of parameters described above is provided as an example and may be two or more. The parameter optimizer 100 may transmit each combination of parameter values according to the number of parameters to the overlay measurement device 200. For example, when the number of parameters is “3” and the set distance is “1”, 27 parameter sets may be transmitted. When the number of parameters is “4” and the set distance is “1”, 81 parameter sets may be transmitted. That is, parameter sets, the number of which correspond to (1+2d)ⁿ(d being a set distance and n being the number of parameters) may be transmitted to the overlay measurement device 200. In this case, a parameter set whose image processing score is already calculated may not be transmitted to the overlay measurement device 200.

For better understanding of the present disclosure, the foregoing and following description is given under the assumption that the number of parameters included in a parameter set is “2”.

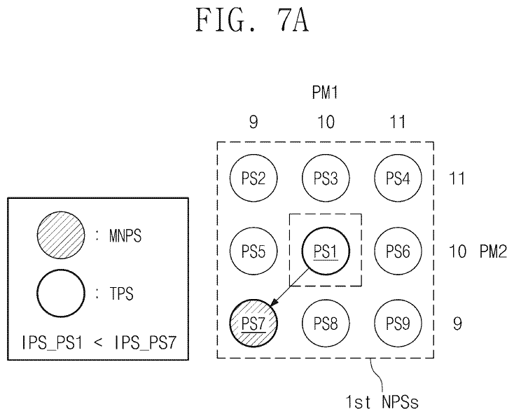

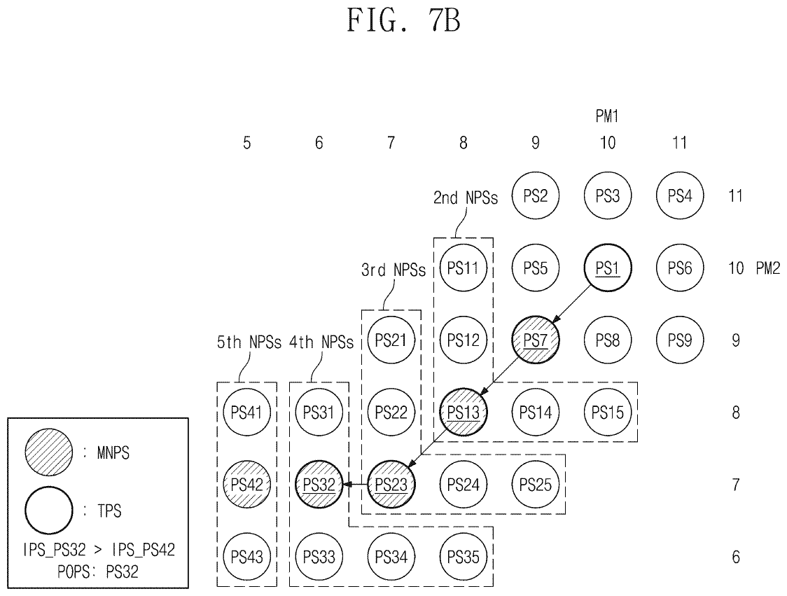

FIGS. 7A and 7B are diagrams for describing an operation of adjusting a target parameter set, according to some implementations of the present disclosure. Referring to FIG. 7A, the parameter optimizer 100 may adjust a target parameter set TPS.

A parameter set may include the first parameter PM1 and the second parameter PM2. It is assumed that a value of the first parameter PM1 included in the parameter set PS1 corresponding to the target parameter set TPS is “10”, a value of the second parameter PM2 included therein is “10”, the adjustment unit of each of the first parameter PM1 and the second parameter PM2 is “1”, and the set distance is “1”.

The parameter optimizer 100 may calculate image processing scores of the parameter set PS1 corresponding to the target parameter set TPS and the parameter sets PS2, PS3, . . . , PS9 corresponding to (e.g., using) first neighboring parameter sets 1st NPSs. In this case, the parameter optimizer 100 may calculate the image processing score by using all the obtained SEM images.

The parameter optimizer 100 may determine a parameter set having the greatest image processing score from among the parameter sets PS2 to PS9 corresponding to the first neighboring parameter sets 1st NPSs as a maximum neighboring parameter set. It is assumed that the image processing score of the parameter set PS7 among the first neighboring parameter sets 1st NPSs is the greatest. A value of the first parameter PM1 included in the parameter set PS7 is “9”, and a value of the second parameter PM2 included therein is “9”.

The parameter optimizer 100 may compare the image processing score of the target parameter set TPS and the image processing score of a maximum neighboring parameter set MNPS. That is, the parameter optimizer 100 may compare an image processing score IPS_PS1 of the parameter set PS1 and an image processing score IPS_PS7 of the parameter set PS7. Based on the image processing score IPS_PS1 of the parameter set PS1 being smaller than the image processing score IPS_PS7 of the parameter set PS7, the parameters included in the target parameter set TPS may be adjusted to have parameter values included in the parameter set PS7. That is, the target parameter set TPS may be adjusted (or changed) to the maximum neighboring parameter set MNPS. The value of the first parameter PM1 of the target parameter set TPS may be adjusted from “10” to “9”, and the value of the second parameter PM2 thereof may be adjusted from “10” to “9”.

Unlike the illustrated example, when the image processing score IPS_PS1 of the parameter set PS1 is greater than or equal to the image processing score IPS_PS7 of the parameter set PS7, the parameter set PS1 may be determined as the primary optimization parameter set. That is, a value of the first parameter PM1 included in the primary optimization parameter set may be determined to be “10”, and a value of the second parameter PM2 included therein may be determined to be “10”. Below, it is assumed that the target parameter set TPS is adjusted (or changed) to the parameter set PS7.

Referring to FIG. 7B, the parameter optimizer 100 may calculate image processing scores of the parameter set PS7 and neighboring parameter sets of the parameter set PS7. In this case, the calculation of the image processing score may be omitted with regard to the parameter sets PS7, PS5, PS1, and PS8 whose image processing scores are already calculated. That is, the parameter optimizer 100 may calculate image processing scores of parameter sets PS11, PS12, . . . , PS15 included in second neighboring parameter sets 2nd NPSs. The parameter optimizer 100 may transmit each of the parameter sets PS11 to PS15 included in the second neighboring parameter sets 2nd NPSs to the overlay measurement device 200. When the parameter optimizer 100 transmits each of the parameter sets PS11 to PS15 to the overlay measurement device 200, the parameter optimizer 100 may transmit the plurality of SEM images SI. The overlay measurement device 200 may output the overlay information OI corresponding to each of the plurality of SEM images SI. The parameter optimizer 100 may calculate image processing scores of the parameter sets PS11 to PS15 included in the second neighboring parameter sets 2nd NPSs based on the received overlay information OI.

It is assumed that the image processing score of the parameter set PS13 among the parameter sets PS11 to PS15 is the greatest. That is, the maximum neighboring parameter set of the second neighboring parameter sets 2nd NPSs is the parameter set PS13. The parameter optimizer 100 may compare the image processing score of the parameter set PS7 corresponding to the target parameter set TPS and the image processing score of the parameter set PS13 corresponding to the maximum neighboring parameter set. Based on the image processing score of the parameter set PS7 being smaller than the image processing score of the parameter set PS13, the target parameter set TPS may be adjusted to the parameter set PS13.

The parameter optimizer 100 may calculate image processing scores of neighboring parameter sets of the parameter set PS13 corresponding to the target parameter set TPS. In this case, the calculation of the image processing score may be omitted with regard to the parameter sets PS7, PS12, and PS14 whose image processing scores are already calculated. The parameter optimizer 100 may calculate image processing scores of third neighboring parameter sets 3rd NPSs. A maximum neighboring parameter set among parameter sets PS21, PS22, . . . , PS25 included in the third neighboring parameter sets 3rd NPSs is the parameter set PS23. The parameter optimizer 100 may compare the image processing score of the parameter set PS13 corresponding to the target parameter set TPS and the image processing score of the parameter set PS23 corresponding to the maximum neighboring parameter set. Based on the image processing score of the parameter set PS13 being smaller than the image processing score of the parameter set PS23, the target parameter set TPS may be adjusted to the parameter set PS23.

The parameter optimizer 100 may calculate image processing scores of fourth neighboring parameter sets 4th NPSs, whose image processing scores are not calculated, from among neighboring parameter sets of the parameter set PS23 corresponding to the target parameter set TPS. A maximum neighboring parameter set among parameter sets PS31, PS32, . . . , PS35 included in the fourth neighboring parameter sets 4th NPSs is the parameter set PS32. The parameter optimizer 100 may compare the image processing score of the parameter set PS23 corresponding to the target parameter set TPS and the image processing score of the parameter set PS32 corresponding to the maximum neighboring parameter set. Based on the image processing score of the parameter set PS23 being smaller than the image processing score of the parameter set PS32, the target parameter set TPS may be adjusted to the parameter set PS32.

The parameter optimizer 100 may calculate image processing scores of fifth neighboring parameter sets 5th NPSs, whose image processing scores are not calculated, from among neighboring parameter sets of the parameter set PS32 corresponding to the target parameter set TPS. A maximum neighboring parameter set among parameter sets PS41, PS42, and PS43 included in the fifth neighboring parameter sets 5th NPSs is the parameter set PS42. The parameter optimizer 100 may compare an image processing score IPS_PS32 of the parameter set PS32 corresponding to the target parameter set TPS and an image processing score IPS_PS42 of the parameter set PS42 corresponding to the maximum neighboring parameter set. Based on the image processing score IPS_PS32 of the parameter set PS32 being greater than or equal than the image processing score IPS_PS42 of the parameter set PS42, the parameter set PS32 corresponding to the target parameter set TPS may be determined as a primary optimization parameter set POPS.

That is, a combination of values of the parameters PM1 and PM2 of the target parameter set TPS is adjusted in order of [10, 10], [9, 9], [8, 8], [7, 7], and [6, 7]. In this case, [6, 7] may be determined as the combination of the values of the parameters PM1 and PM2 of the target parameter set TPS.

The combination [6, 7] of the values of the parameters PM1 and PM2 of the target parameter set TPS is a combination of parameter values optimized with respect to all the obtained SEM images.

In implementations in which the overlay measurement device 200 stores a plurality of SEM images, the operation in which the parameter optimizer 100 transmits the plurality of SEM images to the overlay measurement device 200 may be omitted. The overlay measurement device 200 may store processed SEM images and overlay information, in addition to or instead of the plurality of SEM images.

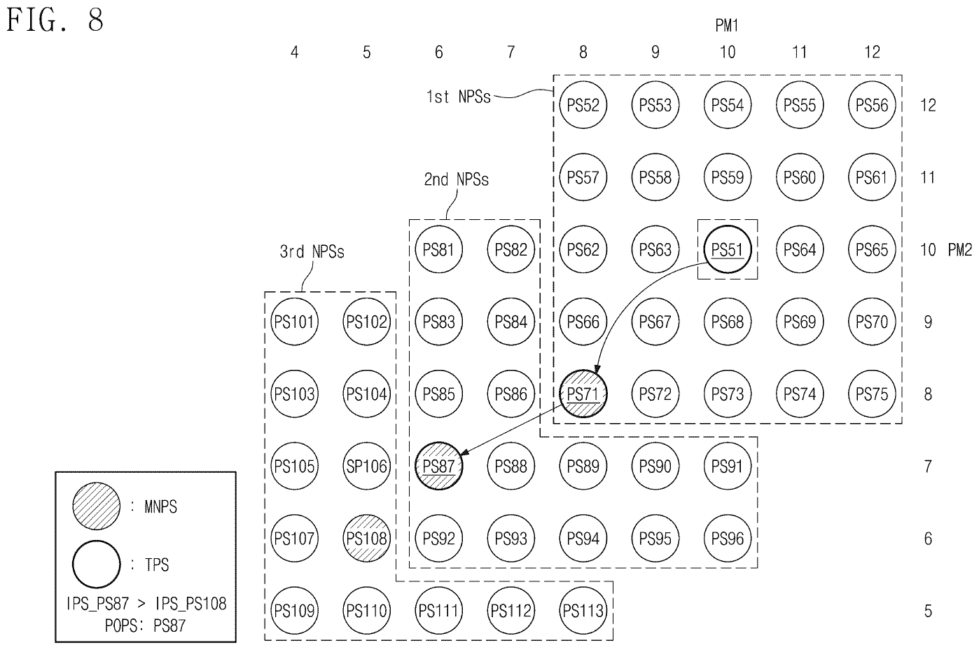

FIG. 8 is a diagram for describing another example of an operation of adjusting a target parameter set, according to some implementations of the present disclosure. Referring to FIG. 8, the parameter optimizer 100 may adjust the target parameter set TPS depending on a set distance.

It is assumed that a value of the first parameter PM1 included in the parameter set PS1 corresponding to the target parameter set TPS is “10”, a value of the second parameter PM2 included therein is “10”, the adjustment unit of each of the first parameter PMI and the second parameter PM2 is “1”, and the set distance is “2”.

The parameter optimizer 100 may calculate image processing scores of the parameter set PS51 corresponding to the target parameter set TPS and parameter sets PS52, PS53, . . . , PS75 corresponding to first neighboring parameter sets 1st NPSs.

A maximum neighboring parameter set among the parameter sets PS52 to PS75 in the first neighboring parameter sets 1st NPSs is the parameter set PS71.

The parameter optimizer 100 may compare the image processing score of the parameter set PS51 corresponding to the target parameter set TPS and the image processing score of the parameter set PS71 corresponding to the maximum neighboring parameter set. Based on the image processing score of the parameter set PS51 being smaller than the image processing score of the parameter set PS71, the target parameter set TPS may be adjusted to the parameter set PS71.

The parameter optimizer 100 may calculate image processing scores of neighboring parameter sets, whose image processing scores are not calculated, from among parameter sets neighboring on the parameter set PS71 and being spaced from the parameter set PS71 as much as the set distance of “2”. That is, the parameter optimizer 100 may calculate image processing scores of parameter sets PS81, PS82, . . . , PS96 corresponding to second neighboring parameter sets 2nd NPSs.

A maximum neighboring parameter set among the parameter sets PS81 to PS96 corresponding to the second neighboring parameter sets 2nd NPSs is the parameter set PS87. The parameter optimizer 100 may compare the image processing score of the parameter set PS71 corresponding to the target parameter set TPS and the image processing score of the parameter set PS87 corresponding to the maximum neighboring parameter set. Based on the image processing score of the parameter set PS71 being smaller than the image processing score of the parameter set PS87, the target parameter set TPS may be adjusted to the parameter set PS87.

The parameter optimizer 100 may calculate image processing scores of neighboring parameter sets, whose image scores are not calculated, from among parameter sets neighboring on the parameter set PS87 and being spaced from the parameter set PS87 as much as the set distance of “2”. That is, the parameter optimizer 100 may calculate image processing scores of parameter sets PS101, PS102, . . . , PS113 corresponding to third neighboring parameter sets 3rd NPSs.

A maximum neighboring parameter set among the parameter sets PS101 to PS113 corresponding to the third neighboring parameter sets 3rd NPSs is the parameter set PS108. The parameter optimizer 100 may compare an image processing score IPS_87 of the parameter set PS87 corresponding to the target parameter set TPS and an image processing score IPS_PS108 of the parameter set PS108 corresponding to the maximum neighboring parameter set. Based on the image processing score of the parameter set PS87 being greater than or equal than the image processing score of the parameter set PS108, the parameter set PS87 corresponding to the target parameter set TPS may be determined as the primary optimization parameter set POPS.

That is, a combination of values of the parameters PM1 and PM2 of the target parameter set TPS is adjusted in order of [10, 10], [8, 8], and [6, 7]. In this case, [6, 7] may be determined as the combination of the values of the parameters PM1 and PM2 of the target parameter set TPS.

The example in which the number of parameters included in a parameter set is “2” and parameter values are adjusted on a second-dimensional plane is described. However, when the number of parameters included in a parameter set is more than “2”, parameter values may be adjusted in consideration of dimensions corresponding to the number of parameters.

For example, when the number of parameters included in a parameter set is “3” and a distance defining a neighbor is “1”, the number of neighboring parameter sets may be “26”. When the number of parameters included in the parameter set is “3”, a combination of parameter values may be considered in a three-dimensional manner. When the number of parameters included in a parameter sets is “4”, the number of neighboring parameter sets may be “80”. When the number of parameters included in a parameter set is “4”, a combination of parameter values may be considered in a four-dimensional manner.

A neighboring parameter distance may have a specific range. For example, when the range of the neighboring parameter is more than 1 and 2 or less and when a target parameter set is the parameter set PS51, the remaining parameter sets other than the parameter sets PS58 to PS60, PS63, PS64, and PS67 to PS69 among the parameter sets PS52 to PS75 corresponding to neighboring parameter sets may be set as neighboring parameter sets.

A neighboring distance of a neighboring parameter set may be set to a variable value. For example, a neighboring distance may be initially set to a relatively great distance and may then be set to a relatively small distance. In contrast, a neighboring distance may be initially set to a relatively small distance and may then be set to a relatively great distance.

The neighboring distance defining a neighboring parameter set may be determined in consideration of the risk of falling into a local optimal solution and the amount of computation necessary to calculate an image processing score.

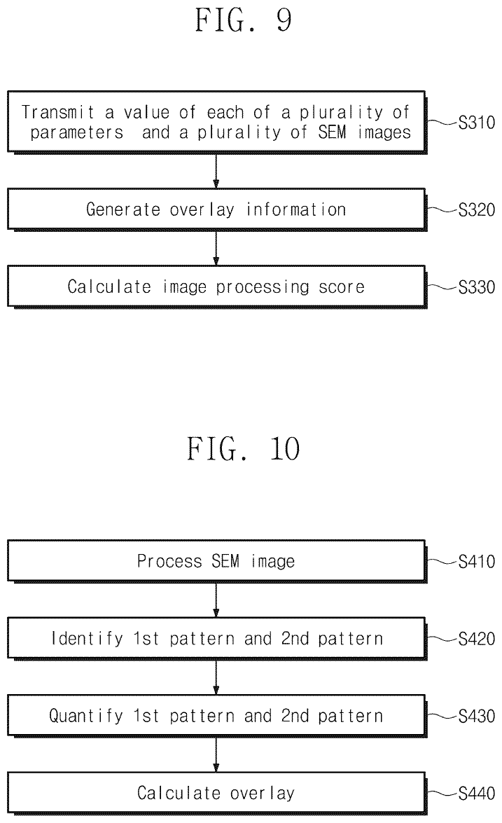

FIG. 9 is a diagram for describing an operation of calculating an image processing score, according to some implementations of the present disclosure. Referring to FIGS. 5 and 9, operation S210, that is, the obtaining of the image processing score may include transmitting a value of each of a plurality of parameters and a plurality of SEM images (S310).

A combination of the values of the plurality of parameters corresponds to a parameter set for calculating an image processing score. For the calculation of the image processing score, the parameter optimizer 100 may transmit a value of each of a plurality of parameters corresponding to a parameter set to the overlay measurement device 200. The parameter optimizer 100 may transmit a plurality of SEM images to the overlay measurement device 200 together with the value of each of the plurality of parameters. The overlay measurement device 200 may receive the plurality of parameter values and the plurality of SEM images from the parameter optimizer 100.

Operation S210, that is, the obtaining of the image processing score may include generating overlay information corresponding to each of the plurality of SEM images (S320). The overlay measurement device 200 may perform image processing and pattern identification based on each parameter value for each of the plurality of SEM images and may generate the overlay information corresponding to each of the plurality of SEM images. The overlay information may include overlay values according to patterns included in the corresponding SEM image. For example, the overlay information may include an overlay value of a first axis (e.g., an X-axis) and an overlay value of a second axis (e.g., a Y-axis) perpendicular to the first axis.

Operation S210, that is, the obtaining of the image processing score may include calculating an image processing score based on overlay settings and overlay information (S330). The overlay settings correspond to an overlay value applied when a first pattern and a second pattern are formed on a semiconductor wafer. The overlay information includes the on-cell overlay received from the overlay measurement device 200 and corresponds to the measured overlay value.

Accordingly, the performance of image processing or pattern identification of the overlay measurement device 200, which is performed for each parameter set, may be evaluated by comparing an overlay value applied when patterns are formed on a semiconductor wafer and an overlay value measured through a scanning electron microscope after the patterns are formed.

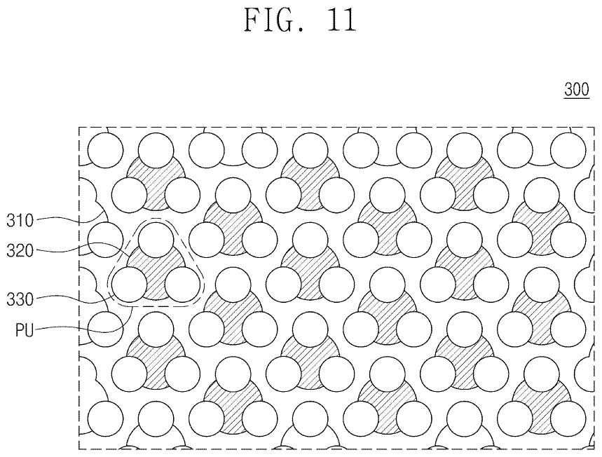

FIG. 10 is a flowchart for describing how to generate overlay information, according to some implementations of the present disclosure. Referring to FIG. 10, operation S320, that is, the generating of the overlay information may include processing an SEM image (S410), identifying patterns (S420), quantifying the patterns (S430), and calculating an overlay based on the quantified patterns (S440).

In operation S410, that is, in the processing of the SEM image, the overlay measurement device 200 may use some or all of the received parameter values. Operation S410, that is, the processing of the SEM image may be performed by the image processing circuit 210 included in the overlay measurement device 200.

In operation S420, that is, in the identifying of the patterns, the overlay measurement device 200 may identify a first pattern and a second pattern on a processed SEM image, which are used to generate the overlay information. In operation S420, that is, in the identifying of the patterns, the overlay measurement device 200 may use some or all of the received parameter values when identifying the first pattern and the second pattern on the processed SEM image. Operation S420, that is, the identifying of the patterns may be performed by the pattern identification circuit 220 included in the overlay measurement device 200.

In operation S430, that is, in the quantifying of the patterns, the overlay measurement device 200 may calculate a reference point of each of first patterns and second patterns for calculating an overlay between the first pattern and the second pattern. Operation S430, that is, the quantifying of the patterns may be performed by the pattern quantification circuit 230 included in the overlay measurement device 200.

In operation S440, that is, in the calculating of the overlay based on the quantified patterns, the overlay measurement device 200 may calculate the overlay based on the reference points of the first patterns and the reference points of the second patterns, which are determined through the quantification. Operation S440, that is, the calculating of the overlay based on the quantified patterns may be performed by the overlay calculator 240 included in the overlay measurement device 200.

FIG. 11 is a diagram illustrating patterns disposed on a semiconductor wafer, according to some implementations of the present disclosure. Referring to FIG. 11, a support pattern 310, support holes 320, and lower electrodes 330 may be disposed (or formed) on a semiconductor wafer 300.

The lower electrode 330 may be formed on the semiconductor wafer 300 in the form of a pillar. The support pattern 310 may be in contact with first sides of all the lower electrodes 330. A second side of the lower electrode 330 may be exposed through the support hole 320. One support hole 320 may correspond to a plurality of lower electrodes 330. According to the example illustrated in FIG. 11, three lower electrodes 330 may be exposed for each support hole 320.

Three lower electrodes 330 corresponding to a single support hole 320 may be treated as a pattern unit PU. A reference point of a first pattern and a reference point of a second pattern may be calculated for each pattern unit PU. For example, for each pattern unit PU, a reference point of a support hole (320) pattern may be calculated, and a reference point of a lower electrode (330) pattern may be calculated. The overlay between the support hole (320) pattern and the lower electrode (330) pattern may be calculated based on a relative position of the reference point of the support hole (320) pattern and the reference point of the lower electrode (330).

For example, the support hole 320 may correspond to the first pattern of FIG. 10, and the lower electrode 330 may correspond to the second pattern.

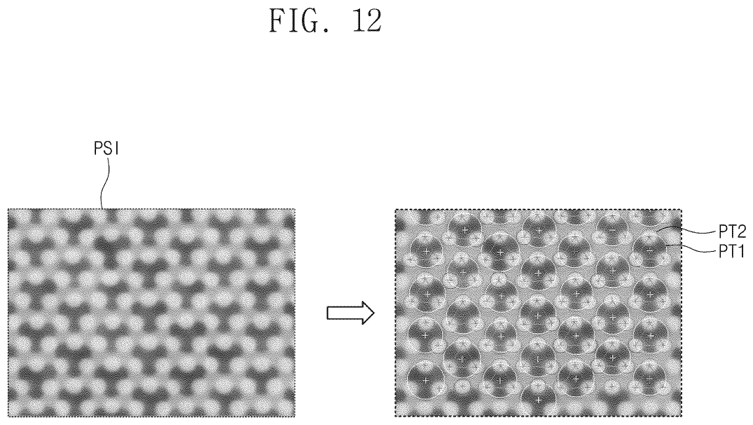

FIG. 12 is a diagram for describing pattern identification and pattern quantification, according to some implementations of the present disclosure. Referring to FIG. 12, the pattern identification circuit 220 may identify a first pattern (PT1) and a second pattern (PT2) on the semiconductor wafer from the processed SEM image PS1.

To identify the first pattern and the second pattern from the processed SEM image SI, the pattern identification circuit 220 may use information about characteristics of the first and second patterns. For example, the information about the first and second patterns may include a maximum/minimum size of each pattern, a maximum value/a minimum value of the ratio of the major axis to the minor axis of the fitting ellipse of each pattern, a threshold voltage of each pattern, etc. The information about the first pattern and the second pattern may be a preset value. In some implementations, the information about the first pattern and the second pattern may be determined by (e.g., may be) a parameter value included in a parameter set. For example, a parameter set may include one or more characteristics of the second pattern, such as a minimum size of the second pattern, a maximum size of the second pattern, a maximum ratio of the major axis to the minor axis of the fitting ellipse of the second pattern, and/or a minimum ratio of the major axis to the minor axis of the fitting ellipse of the second pattern.

The pattern quantification circuit 230 may quantify the first pattern and the second pattern identified through the pattern identification circuit 220. For example, the pattern quantification circuit 230 may quantify the first pattern to determine the reference point of the first pattern. For example, the first pattern may be identified as a circle, and the reference point of the first pattern may be quantified as the center of the identified circle. The pattern quantification circuit 230 may quantify the second pattern to determine the reference point of the second pattern. The reference point of the second pattern may be quantified as the center of a triangle formed of the center points of the identified second patterns.

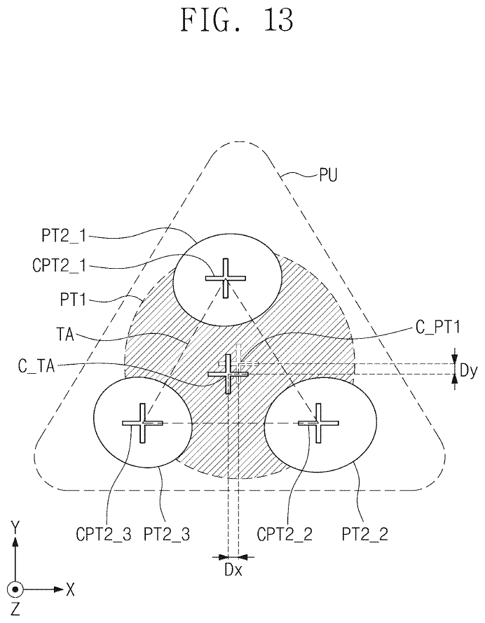

FIG. 13 is a diagram illustrating a first pattern and a second pattern identified in a pattern unit, according to some implementations of the present disclosure. Referring to FIG. 13, the overlay may be calculated based on the first pattern PT1 and the second pattern PT2 for each pattern unit PU.

The support hole 320 of FIG. 11 corresponds to the first pattern PT1, and the lower electrode 330 of FIG. 11 corresponds to the second pattern PT2. The reference point of the first pattern PT1, which is used to calculate the overlay, may be determined as a center point C_PT1 of the first pattern PT1. A reference position of the first pattern PT1 may be determined. The reference position of the first pattern PT1 may correspond to the coordinates of the reference point of the first pattern PT1.

The reference point of the second pattern PT2, which is used to calculate the overlay, may be determined as a center point C_TA of a triangle TA formed by (e.g., having as corners) center points CPT2_1, CPT2_2, and CPT2_3 of second patterns PT2_1, PT2_2, and PT2_3. A reference position of the second pattern PT2 may be determined. The reference position of the second pattern PT2 may correspond to the coordinates of the reference point of the second pattern PT2.

The overlay between the first pattern PT1 and the second patterns PT2_1, PT2_2, and PT2_3 in the pattern unit PU may be calculated depending on a relative position between the center point C_PT1 of the first pattern PT1 and the center point C_TA of the triangle TA.

That is, in the pattern unit PU, the size of the X-axis overlay may be “Dx”, and a direction of the X-axis overlay may be determined as a negative direction of the X-axis. In the pattern unit PU, the size of the Y-axis overlay may be “Dy”, and a direction of the Y-axis overlay may be determined as a negative direction of the Y-axis.

Meanwhile, a plurality of pattern units PU may be identified on the processed SEM image. The overlay corresponding to the SEM image may be determined based on the overlay of each of the plurality of pattern units PU identified on the processed SEM image. For example, the overlay corresponding to the SEM image may be determined as an overlay average value of the plurality of pattern units PU. That is, overlay information corresponding to the SEM image may include an average of first-axis overlay values of the plurality of pattern units PU identified on the processed SEM image and an average of second-axis overlay values of the plurality of pattern units PU identified on the processed SEM image.

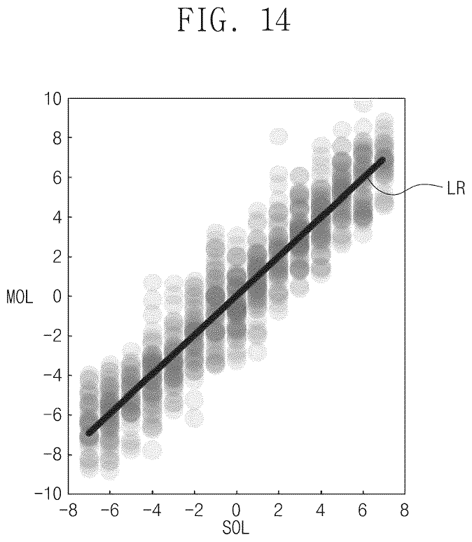

FIG. 14 is a diagram illustrating a linear regression equation which is based on overlay settings and overlay information. Referring to FIG. 14, the image processing score calculator 120 may perform the linear regression analysis based on an overlay setting value SOL included in overlay settings and an overlay measurement value MOL included in overlay information.

The overlay settings may include the overlay setting value SOL used when a first pattern and a second pattern are formed on a semiconductor wafer. The overlay setting value SOL may be variously set depending on a plurality of positions on the semiconductor wafer. That is, the overlay setting value SOL of each of a plurality of SEM images may be variously set.

As described with reference to FIGS. 10 to 13, the overlay measurement device 200 may generate overlay information corresponding to each of the plurality of SEM images. The parameter optimizer 100 may receive the overlay measurement value MOL included in the overlay information from the overlay measurement value MOL.

The parameter optimizer 100 may perform the linear regression analysis between the overlay setting value SOL and the overlay measurement value MOL. In this case, a linear regression equation LR may be generated for each of the first-axis overlay value and the second-axis overlay value. The overlay setting value SOL may correspond to an independent variable in the linear regression analysis, and the overlay measurement value MOL may correspond to a dependent variable in the linear regression analysis.

The parameter optimizer 100 may calculate a slope and a determination coefficient of each of the linear regression equation LR of the first-axis overlay value and the linear regression equation LR of the second-axis overlay value. The slope of the linear regression equation LR means a change of the dependent variable according to a change of the independent variable. The determination coefficient has a range from “0” to “1” and has a value closer to “1” as the relationship between the dependent variable and the independent variable becomes closer.

The parameter optimizer 100 may calculate an image processing score of a parameter set based on the slope and the determination coefficient of the linear regression equation LR. In some implementations, the image processing score of the parameter set may be calculated by Equation 1 below.

$$IPS = - \vert 1 - {SL}_{x} \vert + {R}_{x}^{2} - \vert 1 - {SL}_{y} \vert + {R}_{y}^{2} \qquad [ Equation 1 ]$$

In Equation 1 above, IPS of a parameter set is an image processing score, SLₓ is a slope of the linear regression equation LR of the X-axis overlay, R²ₓ is a determination coefficient of the linear regression equation LR of the X-axis overlay, SL_{y} is a slope of the linear regression equation LR of the Y-axis overlay, and R²_{y} is a determination coefficient of the linear regression equation LR of the Y-axis overlay.

As the slope values SLₓ and SL_{y} of the linear regression equations LR become closer to “1”, the image processing score IPS increases, and as the determination coefficients R²ₓ and R²_{y} become greater, the image processing score IPS of the parameter set increases. Each of the determination coefficients R²ₓ and R²_{y} may have a value between “0” and “1”.

Moreover, the parameter optimizer 100 may further receive the pattern identification rate from the overlay measurement device 200. The parameter optimizer 100 may calculate the image processing score further based on the pattern identification rate. As the pattern identification rate increases, the image processing score IPS may increase.

The parameter optimizer 100 may further receive the quantification success rate from the overlay measurement device 200. The parameter optimizer 100 may calculate the image processing score further based on the received quantification success rate. As the quantification success rate increases, the image processing score IPS may increase. The parameter optimizer 100 may use only one of the pattern identification rate and the quantification success rate.

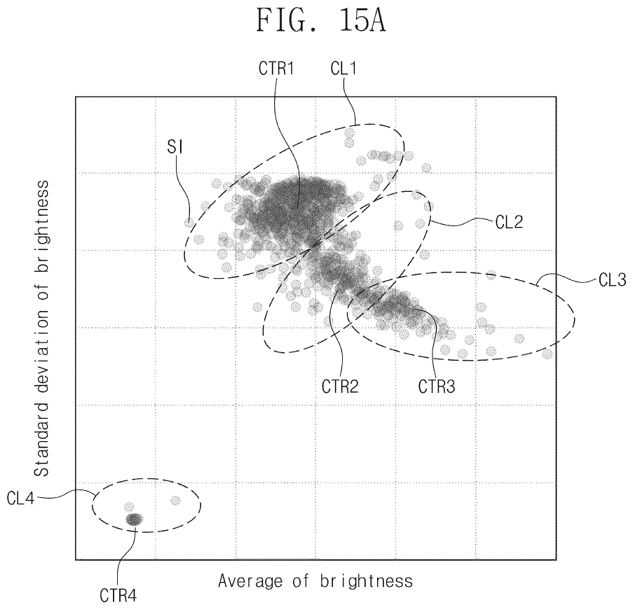

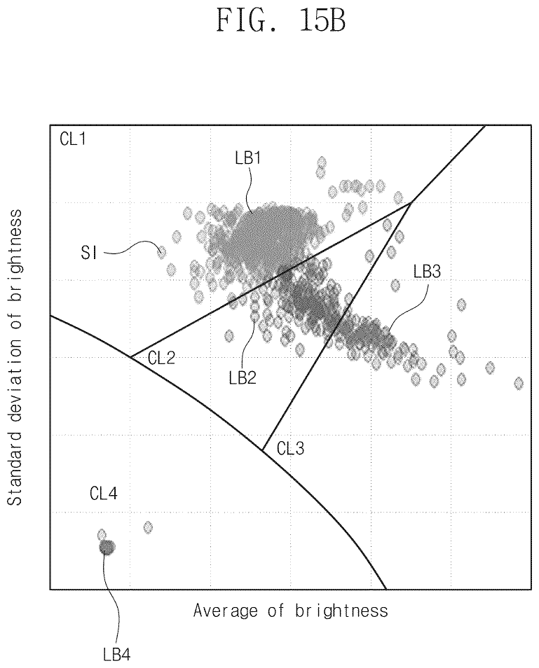

FIGS. 15A and 15B are diagrams illustrating a plurality of SEM images depending on image attributes, according to some implementations of the present disclosure. Referring to FIG. 15, the plurality of SEM images SI may be plotted based on image attributes.

The image attributes may include the average of brightness and the standard deviation of brightness. SEM images SI that are relatively closely plotted may have similar image attributes. The parameter optimizer 100 may cluster the plurality of SEM images SI in a plurality of clusters CL1, CL2, CL3, and CL4 based on the image attributes.

The parameter optimizer 100 may determine centroids of the clusters CL1 to CL4 by using the K-means method. When the parameter optimizer 100 determines the number of clusters, the parameter optimizer 100 may use an elbow method of determining the number of clusters by using a sum of squares of error (EES) graph or a silhouette method of determining the number of clusters based on data cohesion within a cluster and data separation between clusters. The parameter optimizer 100 may set initial centroids depending on the number of clusters thus determined. The parameter optimizer 100 may allocate the SEM images SI in the clusters CL1 to CL4 and may reset centroids CTR1, CTR2, CTR3, and CTR4 for the allocated SEM images SI. The parameter optimizer 100 may repeat the allocation of the SEM images SI and the resetting of the centroids CTR1 to CTR4 until there is no movement of the centroids CTR1 to CTR4.

The parameter optimizer 100 may use the K-nearest neighbor method in which classification is made with reference to SEM images SI plotted around the centroids CTR1 to CTR4 determined through the K-means method. According to the above description, the parameter optimizer 100 may label the plurality of SEM images SI so as to correspond to one of the clusters CL1 to CL4. SEM images may be labeled by applying the K-nearest neighbor method from the centroids CTR1 to CTR4 of the clusters CL1 to CL4.

Referring to FIG. 15B, the plurality of SEM images may be labeled as labels LB1, LB2, LB3, and LB4 respectively corresponding in the clusters CL1 to CL4. For example, in the plurality of SEM images SI, some corresponding to the first cluster CL1 may be labeled as the first label LB1, others corresponding to the second cluster CL2 may be labeled as the second label LB2, others corresponding to the third cluster CL3 may be labeled as the third label LB3, and the others corresponding to the fourth cluster CL4 may be labeled as the fourth label LB4.

SEM images SI labeled as the same label are included in the same cluster. SEM images SI included in the same cluster may share similar image attributes. The parameter optimizer 100 may additionally optimize a parameter set for each of the clusters CL1 to CL4. The parameter optimizer 100 may determine the secondary optimization parameter set corresponding to each of the clusters CL1 to CL4 based on the plurality of SEM images SI included in each of the clusters CL1 to CL4 and the primary optimization parameter set POPS.

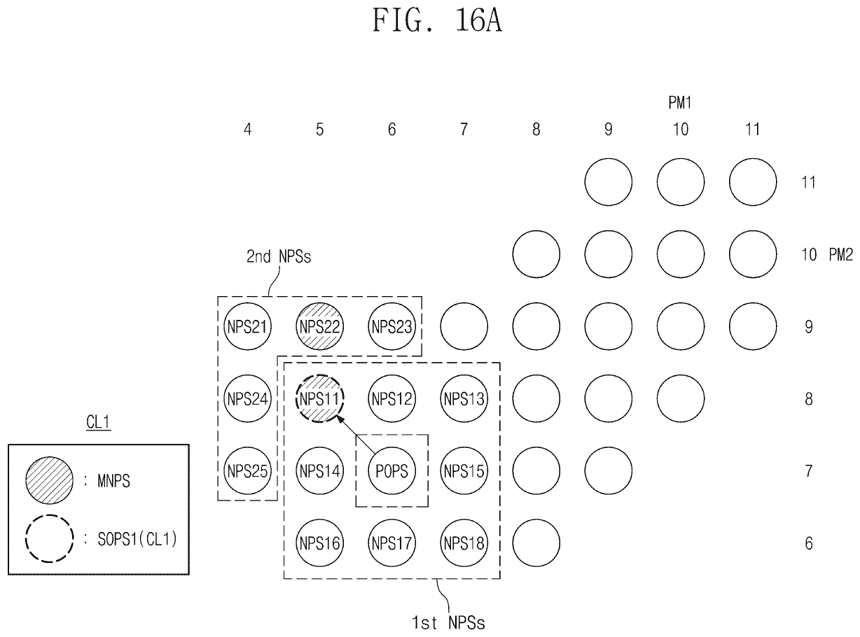

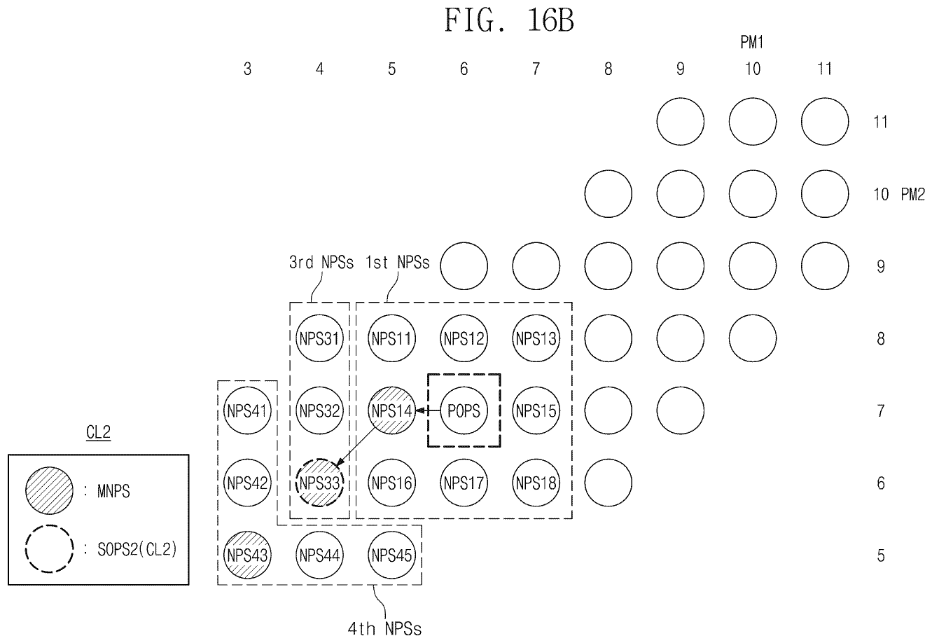

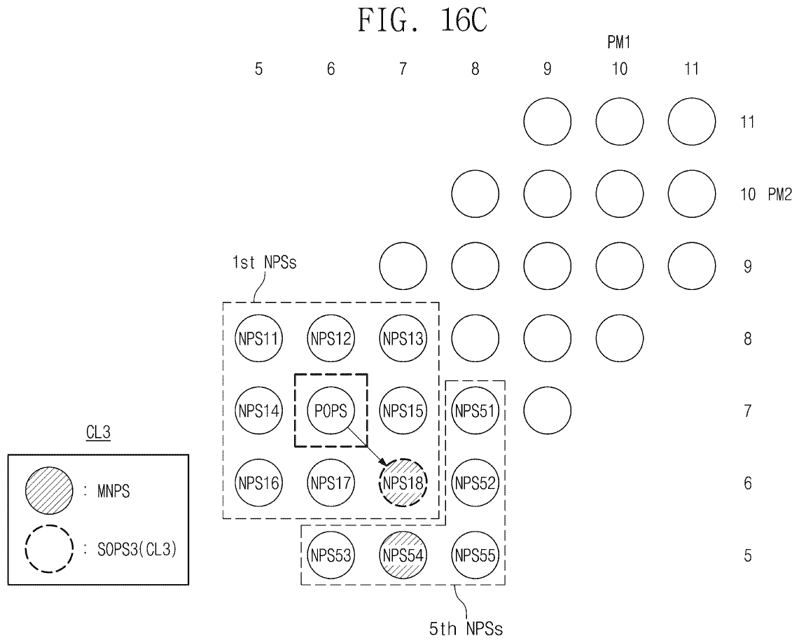

FIGS. 16A to 16C are diagrams illustrating a secondary optimization parameter set for each of a plurality of clusters. Referring to FIGS. 15B and 16A, the parameter optimizer 100 may determine a first secondary optimization parameter set SOPS1 corresponding to the first cluster CL1 based on the SEM images included in the first cluster CL1 and the primary optimization parameter set POPS.

The parameter optimizer 100 may generate image processing scores of the primary optimization parameter set POPS and the first neighboring parameter sets 1st NPSs based on the SEM images included in the first cluster CL1. When the parameter optimizer 100 generates the image processing scores of the primary optimization parameter set POPS and the first neighboring parameter sets 1st NPSs, the parameter optimizer 100 may use the SEM images included in the first cluster CL1. That is, the parameter optimizer 100 may generate the image processing scores of the primary optimization parameter set POPS and the first neighboring parameter sets 1st NPSs by using only the SEM images labeled as the first label LB1. An image processing score calculated by using SEM images labeled as the first label LB1 may be different from an image processing score calculated by using all the obtained SEM images.

In detail, the parameter optimizer 100 may transmit the primary optimization parameter set POPS and the SEM image labeled as the first label LB1 from among the plurality of SEM images to the overlay measurement device 200.

The overlay measurement device 200 may perform image processing and pattern identification based on the primary optimization parameter set POPS and may generate overlay information for each of the SEM images labeled as the first label LB1.

The parameter optimizer 100 may calculate an image processing score corresponding to the primary optimization parameter set POPS based on the overlay settings and the overlay information of each of the SEM images labeled as the first label LB1. Likewise, the parameter optimizer 100 may calculate an image processing score of each of first neighboring parameter sets 1st NPSs by using the SEM images labeled as the first label LB1.

The parameter optimizer 100 may adjust at least one of a plurality of parameters corresponding to the first cluster CL1 based on the image processing scores of the first cluster CL1. In detail, the parameter optimizer 100 may compare the image processing score of the primary optimization parameter set POPS with the image processing score of the neighboring parameter set NPS11 being the maximum neighboring parameter set MNPS, whose image processing score is the greatest, from among the first neighboring parameter sets 1st NPSs.

Based on the image processing score of the primary optimization parameter set POPS being smaller than the image processing score of the neighboring parameter set NPS11, the parameter optimizer 100 calculates an image processing score of each of second neighboring parameter sets 2nd NPSs.

The parameter optimizer 100 may compare the image processing score of the neighboring parameter set NPS11 with the image processing score of the 22nd neighboring parameter set NPS22 being the maximum neighboring parameter set MNPS, whose image processing score is the greatest, from among the second neighboring parameter sets 2nd NPSs.

Based on the image processing score of the neighboring parameter set NPS11 being greater than or equal to the image processing score of the 22nd neighboring parameter set NPS22, the parameter optimizer 100 may determine that the neighboring parameter set NPS11 is the secondary optimization parameter set corresponding to the first cluster CL1. With regard to the first cluster CL1, as there is performed the fine tuning from the primary optimization parameter set POPS to the first secondary optimization parameter set SOPS1, a value of the first parameter PM1 may be adjusted from “6” to “5”, and a value of the second parameter PM2 may be adjusted from “7” to “8”.

Compared to the primary optimization parameter set POPS, the first secondary optimization parameter set SOPS1 corresponds to an image parameter set further optimized with respect to the SEM images included in the first cluster CL1.

Referring to FIGS. 15B and 16B, the parameter optimizer 100 may determine a second secondary optimization parameter set SOPS2 corresponding to the second cluster CL2 based on the plurality SEM images included in the second cluster CL2 and the primary optimization parameter set POPS.

The parameter optimizer 100 may generate image processing scores of the primary optimization parameter set POPS and the first neighboring parameter sets 1st NPSs based on the SEM images included in the second cluster CL2. In this case, the parameter optimizer 100 may use the plurality of SEM images labeled as the second label LB2.

The parameter optimizer 100 may compare the image processing score of the primary optimization parameter set POPS with the image processing score of the neighboring parameter set NPS14 being the maximum neighboring parameter set MNPS, whose image processing score is the greatest, from among the first neighboring parameter sets 1st NPSs.

Based on the image processing score of the primary optimization parameter set POPS being smaller than the image processing score of the neighboring parameter set NPS14, the parameter optimizer 100 calculate an image processing score of each of third neighboring parameter sets 3rd NPSs.

The parameter optimizer 100 may compare the image processing score of the neighboring parameter set NPS14 with the image processing score of the neighboring parameter set NPS33 being the maximum neighboring parameter set MNPS, whose image processing score is the greatest, from among the third neighboring parameter sets 3rd NPSs.

Based on the image processing score of the neighboring parameter set NPS14 being smaller than the image processing score of the 33rd neighboring parameter set NPS33, the parameter optimizer 100 calculate an image processing score of each of fourth neighboring parameter sets 4th NPSs.

The parameter optimizer 100 may compare the image processing score of the neighboring parameter set NPS33 with the image processing score of the 43rd neighboring parameter set NPS43 being the maximum neighboring parameter set MNPS, whose image processing score is the greatest, from among the fourth neighboring parameter sets 4th NPSs.

Based on the image processing score of the neighboring parameter set NPS33 being greater than or equal to the image processing score of the neighboring parameter set NPS43, the parameter optimizer 100 may determine that the neighboring parameter set NPS33 is the second secondary optimization parameter set SOPS2 corresponding to the second cluster CL2. With regard to the second cluster CL2, as there is performed the fine tuning from the primary optimization parameter set POPS to the second secondary optimization parameter set SOPS2, a value of the first parameter PM1 may be adjusted from “6” to “4”, and a value of the second parameter PM2 may be adjusted from “7” to the “6”.

Comparing to the primary optimization parameter set POPS, the second secondary optimization parameter set SOPS2 corresponds to an image parameter set further optimized with respect to the SEM images included in the second cluster CL2.

Referring to FIGS. 15B and 16C, the parameter optimizer 100 may determine a third secondary optimization parameter set SOPS3 corresponding to the third cluster CL3 based on the plurality SEM images included in the third cluster CL3 and the primary optimization parameter set POPS.

The parameter optimizer 100 may generate image processing scores of the primary optimization parameter set POPS and the first neighboring parameter sets 1st NPSs of the primary optimization parameter set POPS by using the plurality of SEM images labeled as the third label LB3.

The parameter optimizer 100 may compare the image processing score of the primary optimization parameter set POPS with the image processing score of the neighboring parameter set NPS18 being the maximum neighboring parameter set MNPS, whose image processing score is the greatest, from among the first neighboring parameter sets 1st NPSs.

Based on the image processing score of the primary optimization parameter set POPS being smaller than the image processing score of the neighboring parameter set NPS18, the parameter optimizer 100 calculate an image processing score of each of fifth neighboring parameter sets 5th NPSs.

The parameter optimizer 100 may compare the image processing score of the neighboring parameter set NPS18 with the image processing score of the neighboring parameter set NPS54 being the maximum neighboring parameter set MNPS, whose image processing score is the greatest, from among the fifth neighboring parameter sets 5th NPSs.

Based on the image processing score of the neighboring parameter set NPS18 being greater than or equal to the image processing score of the neighboring parameter set NPS54, the parameter optimizer 100 may determine that the neighboring parameter set NPS18 is the third secondary optimization parameter set SOPS3 corresponding to the third cluster CL3. With regard to the third cluster CL3, as there is performed the fine tuning from the primary optimization parameter set POPS to the third secondary optimization parameter set SOPS3, a value of the first parameter PM1 may be adjusted from “6” to “7”, and a value of the second parameter PM2 may be adjusted from “7” to the “6”.

Comparing to the primary optimization parameter set POPS, the third secondary optimization parameter set SOPS3 corresponds to an image parameter set further optimized with respect to the SEM images included in the third cluster CL3.

Meanwhile, when the overlay measurement device 200 stores the plurality of SEM images, the parameter optimizer 100 may transmit information of SEM images included in a plurality of clusters to the overlay measurement device 200, and the overlay measurement device 200 may label the plurality of SEM images as a label corresponding to a cluster. Meanwhile, the overlay measurement device 200 may cluster the plurality of SEM images to the plurality of clusters based on image attributes.

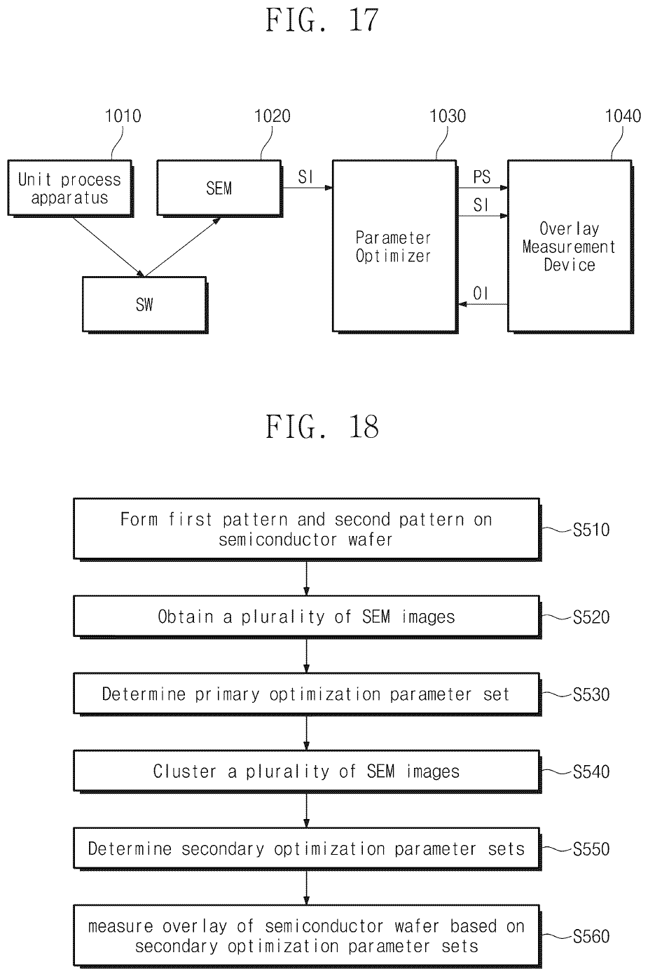

FIG. 17 is a diagram illustrating another example of an on-cell overlay measurement system according to some implementations of the present disclosure. Referring to FIG. 17, an on-cell overlay measurement system may include a unit process apparatus 1010, a scanning electron microscope 1020, a parameter optimizer 1030, and an overlay measurement device 1040.

The unit process apparatus 1010 may etch a semiconductor wafer SW or a thin film on the semiconductor wafer SW by using a photoresist pattern as an etching mask. Also, the unit process apparatus 1010 may polish the semiconductor wafer SW or the thin film for planarization and may perform various processes for forming a first pattern and a second pattern on the semiconductor wafer SW. The unit process apparatus 1010 may form the first pattern and may then form the second pattern based on overlay settings. The overlay settings may be parameters of the unit process apparatus 1010 used when the first pattern and the second pattern are formed on the semiconductor wafer. Assuming that the first pattern and the second pattern are ideally formed according to the settings of the unit process device 1010, the actual overlay values of the first pattern and the second pattern may correspond to the overlay setting values used when the first pattern and the second pattern are formed. For example, assume that the x-axis overlay setting value of the unit process apparatus 1010 is ‘a’ nanometer and the y-axis overlay setting value is ‘b’ nanometers when the first pattern and the second pattern are formed ('a′ and ‘b’ are the given values). The actual x-axis overlay value between the first pattern and the second pattern formed on the semiconductor wafer SW may be ‘a’ nanometer, and the actual y-axis overlay value may be ‘b’ nanometers. On the other hand, when the unit processing apparatus 1010 processes the semiconductor wafer SW, the overlay setting values and the actual overlay values may differ due to various causes.

The scanning electron microscope 1020 may photograph the semiconductor wafer SW. The scanning electron microscope 1020 may obtain an SEM image from the semiconductor wafer SW on which the first pattern and the second pattern are disposed based on the overlay settings. The scanning electron microscope 1020 may generate the plurality of SEM images SI respectively corresponding to a plurality of positions on the semiconductor wafer SW. The scanning electron microscope 1020 may transmit the plurality of SEM images SI to the parameter optimizer 1030. In some implementations, the scanning electron microscope 1020 may transmit the plurality of SEM images SI to the overlay measurement device 1040.

The parameter optimizer 1030 may receive the SEM image SI from the scanning electron microscope 1020. The parameter optimizer 1030 may transmit the parameter set PS and the SEM image SI to the overlay measurement device 1040. The parameter optimizer 1030 may correspond to the parameter optimizer 100 of FIG. 1.

The parameter optimizer 1030 may receive the plurality of SEM image SI from the scanning electron microscope 1020. The parameter optimizer 1030 may determine the primary optimization parameter set based on the overlay settings of the plurality of SEM images SI and the overlay information received from the overlay measurement device 1040. The parameter optimizer 1030 may cluster the plurality of SEM images SI in a plurality of clusters based on image attributes. The parameter optimizer 1030 may determine the secondary optimization parameter set corresponding to each of the plurality of clusters based on the SEM images SI included in each of the plurality of clusters, the overlay settings, the overlay information, and the primary optimization parameter set.

To determine the primary optimization parameter set or the secondary optimization parameter set, the parameter optimizer 1030 may calculate image processing scores of a specific parameter set and neighboring parameter sets of the specific parameter set. The parameter optimizer 1030 may adjust one or more parameters included in a parameter set based on the image processing scores. In this case, the parameter optimizer 1030 may use some or all of the SEM images SI received from the scanning electron microscope 1020.

The overlay measurement device 1040 may generate overlay information corresponding to an SEM image based on the parameter set PS and the SEM image SI. The overlay measurement device 1040 may process the received SEM image SI based on the parameter set and may identify a first pattern and a second pattern on the processed SEM image SI. The overlay measurement device 1040 may quantify the identified first and second patterns. The overlay measurement device 1040 may generate the overlay information based on the quantified first and second patterns and may transmit the overlay information to the parameter optimizer 1030. The overlay measurement device 1040 may calculate the pattern identification rate or the quantification success rate according to the identification of the first pattern and the second pattern. The overlay measurement device 1040 may correspond to the overlay measurement device 200 of FIG. 1.

FIG. 18 is a flowchart illustrating an on-cell overlay measurement method according to some implementations of the present disclosure. Referring to FIGS. 17 and 18, the on-cell overlay measurement method may include forming a first pattern and a second pattern on a semiconductor wafer based on overlay settings (S510), obtaining a plurality of SEM images respectively corresponding to a plurality of positions of the semiconductor wafer (S520), determining a primary optimization parameter set based on the plurality of SEM images (S530), clustering the plurality of SEM images in a plurality of clusters (S540), determining secondary optimization parameter sets based on a plurality of SEM images included in each of the plurality of clusters and the primary optimization parameter set (S550), and measuring an overlay of the semiconductor wafer based on the secondary optimization parameter sets (S560).

Operation S510, that is, the forming of the first pattern and the second pattern on the semiconductor wafer based on the overlay settings may be performed by the unit process apparatus 1010. The unit process apparatus 1010 may apply the overlay settings when forming the first pattern and the second pattern on the semiconductor wafer. The first pattern and the second pattern may be aligned based on a set overlay value.

Operation S520, that is, the obtaining of the plurality of SEM images respectively corresponding to the plurality of positions of the semiconductor wafer may be performed by the scanning electron microscope 1020 and the parameter optimizer 1030. The scanning electron microscope 1020 may photograph SEM images on the plurality of positions of the semiconductor wafer. The scanning electron microscope 1020 may transmit the plurality of SEM images SI corresponding to raw image data to the parameter optimizer 1030.

Operation S530, that is, the determining of the primary optimization parameter set based on the plurality of SEM images may be performed by the parameter optimizer 1030 and the overlay measurement device 1040. The parameter optimizer 1030 may transmit the plurality of SEM images, which are received from the scanning electron microscope 1020 with regard to a single parameter set, to the overlay measurement device 1040. The overlay measurement device 1040 may generate overlay information corresponding to each of the plurality of SEM images SI associated with a single parameter set. The generated overlay information may be transmitted to the parameter optimizer 1030. The parameter optimizer 1030 may calculate an image processing score of the parameter set based on the overlay settings and the overlay information of each of the plurality of SEM images. The parameter optimizer 1030 may calculate image processing scores of a target parameter set and neighboring parameter sets. The parameter optimizer 1030 may compare the image processing score of the target parameter image with the image processing score of a maximum neighboring parameter set. The parameter optimizer 1030 may adjust the target parameter set based on a comparison result. The parameter optimizer 1030 may determine the primary optimization parameter set by repeatedly adjusting the target parameter set.

Operation S540, that is, the clustering of the plurality of SEM images to the plurality of clusters may be performed by the parameter optimizer 1030. The parameter optimizer 1030 may cluster the plurality of SEM image in a plurality of clusters based on image attributes. When the parameter optimizer 1030 clusters the plurality of SEM images, the parameter optimizer 1030 may use the K-means cluster or the K-nearest neighbor cluster. The parameter optimizer 1030 may label SEM images as a label corresponding to a cluster.

Operation S550, that is, the determining of the secondary optimization parameter sets based on the plurality of SEM images included in each of the plurality of clusters and the primary optimization parameter set may be performed by the parameter optimizer 1030 and the overlay measurement device 1040. The parameter optimizer 1030 may transmit, to the overlay measurement device 1040, SEM images labeled as one label from among the plurality of SEM images and a single parameter set. The overlay measurement device 1040 may generate overlay information of the labeled SEM images thus received. The parameter optimizer 1030 may calculate an image processing score of a parameter set based on overlay settings and the overlay information of the labeled SEM images. The parameter optimizer 1030 may determine the secondary optimization parameter set by calculating an image processing score of the primary optimization parameter set and image processing scores of neighboring parameter sets and adjusting parameter values. The parameter optimizer 1030 may determine the secondary optimization parameter set for each of the plurality of clusters. That is, the primary optimization parameter set may be finely tuned to the secondary optimization parameter set depending on image attributes.

Operation S560, that is, the measuring of the overlay of the semiconductor wafer based on the secondary optimization parameter sets may be performed by the overlay measurement device 1040. The overlay measurement device 1040 may use the secondary optimization parameter set of each of the plurality of clusters and the labeled SEM images. According to the above description, the overlay measurement device 1040 may obtain overlay information to which the image attributes are applied. The obtained overlay information may be provided through a display device.

The parameter optimizer 100 may determine the optimized parameter set without performing performance evaluation of all parameter sets capable of being combined. That is, a time and the amount of computation necessary to determine parameters used in image processing and pattern identification may decrease.

The parameter optimizer 100 may finely tune the optimized parameter set based on the image attributes of the SEM images SI. This may mean that the accuracy of the on-cell overlay measured from the semiconductor wafer increases.

According to some implementations of the present disclosure, an overlay measurement method may reduce the burden on computation necessary to determine an optimal parameter value by determining a primary optimization parameter set, clustering semiconductor wafer images depending on image attributes, and determining a secondary optimization parameter set for each cluster, and may determine an optimal parameter in consideration of image attributes.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the present disclosure has been described with reference to implementations thereof, it will be apparent to those of ordinary skill in the art that various changes and modifications may be made thereto without departing from the spirit and scope of the present disclosure.

What is claimed is:

1. A parameter optimization method comprising:
obtaining a plurality of SEM images portraying respective positions of a semiconductor wafer, wherein a first pattern and a second pattern are disposed on the semiconductor wafer, and wherein a relative positioning between the first pattern and the second pattern is based on overlay settings;
determining a primary optimization parameter set based on the plurality of SEM images, the primary optimization parameter set comprising one or more image processing parameters;
clustering the plurality of SEM images in a plurality of clusters based on image attributes of the plurality of SEM images; and
determining a secondary optimization parameter set corresponding to each cluster of the plurality of clusters, based on SEM images included in the cluster and based on the primary optimization parameter set.

2. The parameter optimization method of claim 1, wherein determining the primary optimization parameter set comprises:
processing the plurality of SEM images using a target parameter set and neighboring parameter sets of the target parameter set, to obtain, for each of the target parameter set and the neighboring parameter sets, an image processing score; and
based on the image processing score of the target parameter set being less than a maximum image processing score of the image processing scores of the neighboring parameter sets, adjusting the target parameter set to the maximum neighboring parameter set, or
based on the image processing score of the target parameter set being greater than or equal to the maximum image processing score of the image processing scores of the neighboring parameter sets, determining that the target parameter set is the primary optimization parameter set.

3. The parameter optimization method of claim 2, wherein processing the plurality of SEM images using a first parameter set of the target parameter set and the neighboring parameter sets comprises:
generating overlay information corresponding to each of the plurality of SEM images using the first parameter set; and
determining an image processing score of the first parameter set based on the overlay settings and the overlay information corresponding to each of the plurality of SEM images.

4. The parameter optimization method of claim 3, wherein determining the image processing score of the first parameter set is based on a slope and a determination coefficient of a linear regression equation corresponding to the overlay settings and the overlay information corresponding to each of the plurality of SEM images.

5. The parameter optimization method of claim 4, wherein the overlay information corresponding to each of the plurality of SEM images includes an overlay value of a first axis on the semiconductor wafer and an overlay value of a second axis perpendicular to the first axis.

6. The parameter optimization method of claim 3, wherein generating the overlay information corresponding to each of the plurality of SEM images comprises:
identifying the first pattern and the second pattern in the SEM image using the first parameter set; and
calculating the overlay information based on a relative positioning between the identified first pattern and the identified second pattern in the SEM image.

7. The parameter optimization method of claim 6, wherein determining the image processing score of the first parameter set is based on a quantification success rate of the first pattern and the second pattern.

8. The parameter optimization method of claim 6, wherein the first parameter set comprises a plurality of parameters, and wherein processing each SEM image of the plurality of SEM images comprises:
performing first processing on the SEM image using a first parameter of the plurality of parameters; and
performing second processing on a result of the first processing based on a second parameter of the plurality of parameters.

9. The parameter optimization method of claim 8, wherein the first processing comprises at least one of blur processing, thresholding processing, morphological transformation processing, erode processing, or dilation processing.

10. The parameter optimization method of claim 8, wherein the second processing comprises pattern identification, and
wherein the second parameter is associated with a characteristic of the first pattern.

11. The parameter optimization method of claim 1, wherein the image attributes comprise an average of image brightness and a standard deviation of image brightness.

12. The parameter optimization method of claim 1, wherein clustering the plurality of SEM images in the plurality of clusters comprises:
determining centroids of the plurality of clusters using a K-means method; and
labeling each of the plurality of SEM images using a K-nearest neighbor (K-NN) method based on the centroids.

13. The parameter optimization method of claim 1, wherein determining the secondary optimization parameter set corresponding to each of the plurality of clusters includes:
determining a secondary optimization parameter set corresponding to a first cluster of the plurality of clusters based on SEM images included in the first cluster; and
determining a secondary optimization parameter set corresponding to a second cluster of the plurality of clusters based SEM images included in the second cluster.

14. The parameter optimization method of claim 13, wherein determining the secondary optimization parameter set corresponding to the first cluster comprises:
generating image processing scores of the first cluster using each of the primary optimization parameter set and neighboring parameter sets based on the SEM images included in the first cluster; and
selecting at least one of a plurality of image processing parameters corresponding to the first cluster based on the image processing scores of the first cluster, and
wherein determining the secondary optimization parameter set corresponding to the second cluster comprises:
generating image processing scores of the second cluster using each of the primary optimization parameter set and the neighboring parameter sets based on the SEM images included in the second cluster; and
selecting at least one of a plurality of image processing parameters corresponding to the second cluster based on the image processing scores of the second cluster.

15. The parameter optimization method of claim 14, wherein selecting the at least one of the plurality of image processing parameters corresponding to the first cluster comprises:
based on an image processing score of the primary optimization parameter set of the first cluster being less than a maximum image processing score of image processing scores of the neighboring parameter sets, changing a plurality of parameters corresponding to the first cluster to match the maximum neighboring parameter set, or
based on the image processing score of the primary optimization parameter set being greater than or equal to the maximum image processing score of the image processing scores of the neighboring parameter sets, determining the plurality of parameters corresponding to the first cluster as a secondary optimization parameter set of the first cluster.

16. The parameter optimization method of claim 1, wherein the first pattern on the semiconductor wafer is a lower electrode of a cell capacitor, and the second pattern on the semiconductor wafer is a support hole.

17. An on-cell overlay measurement system comprising:
a scanning electron microscope configured to capture a plurality of SEM images of a semiconductor wafer on which a first pattern and a second pattern are disposed, wherein a relative positioning between the first pattern and the second pattern is based on overlay settings;
a parameter optimizer configured to receive the plurality of SEM images from the scanning electron microscope and to transmit a parameter set and the plurality of SEM images to an overlay measurement device; and
the overlay measurement device, wherein the overlay measurement device is configured to generate overlay information of the plurality of SEM images based on the parameter set and the plurality of SEM images,
wherein the parameter optimizer is configured to:
determine a primary optimization parameter set based on the overlay settings and based on the overlay information of the plurality of SEM images, the primary optimization parameter set comprising one or more image processing parameters;
cluster the plurality of SEM images in a plurality of clusters based on image attributes of the plurality of SEM images; and
determine a secondary optimization parameter set corresponding to each of the plurality of clusters based on the primary optimization parameter set, based on the overlay settings, and based on overlay information of SEM images included in the cluster.

18. The on-cell overlay measurement system of claim 17, wherein the overlay measurement device is configured to:
process a first SEM image of the plurality of SEM images using the parameter set;
identify the first pattern and the second pattern in the first SEM image based on the processing using the parameter set;
determine reference positions of the first pattern and the second pattern; and
generate overlay information of the first SEM image based on the reference positions.

19. The on-cell overlay measurement system of claim 17, wherein the parameter optimizer is configured to:
process the plurality of SEM images using a target parameter set and neighboring parameter sets;
determine, based on the overlay settings, based on the processing of the plurality of SEM images using a target parameter set and neighboring parameter sets, and based on the overlay information of the plurality of SEM images, imaging processing scores for each of the target parameter set and the neighboring parameter sets; and
adjust the target parameter set based on the image processing scores.

20. An on-cell overlay measurement method comprising:
forming a first pattern and a second pattern in a semiconductor wafer based on overlay settings;
capturing a plurality of SEM images associated with a plurality of positions of the semiconductor wafer;
determining a primary optimization parameter set based on the plurality of SEM images, the primary optimization parameter set comprising one or more image processing parameters;
clustering the plurality of SEM images into a plurality of clusters based on image attributes of the plurality of SEM images;
determining a secondary optimization parameter set corresponding to each of the plurality of clusters based on SEM images included in each of the plurality of clusters and based on the primary optimization parameter set; and
measuring an overlay of each of the plurality of SEM images using the secondary optimization parameter set corresponding to each of the plurality of clusters.
